(19) United States
(12) Patent Application Publication
(10) Pub. No.: US 2026/0136710 A1
(43) Pub. Date: May 14, 2026

(54) LIGHT-EMITTING DEVICE, METHOD OF MANUFACTURING DISPLAY DEVICE, AND IMAGE DISPLAY APPARATUS

(71) Applicant: SONY SEMICONDUCTOR SOLUTIONS CORPORATION, Kanagawa (JP)

(72) Inventors: Nobutoshi FUJII, Kanagawa (JP); Suguru SAITO, Kanagawa (JP); Shunsuke FURUSE, Kanagawa (JP); Sotetsu SAITO, Tokyo (JP)

(73) Assignee: SONY SEMICONDUCTOR SOLUTIONS CORPORATION, Kanagawa (JP)

(21) Appl. No.: 19/118,736

(22) PCT Filed: Oct. 25, 2023
(86) PCT No.: PCT/JP2023/038416

§ 371 Date: Apr. 4, 2025

(30) Foreign Application Priority Data
Nov. 1, 2022 (JP) 2022-175801

(51) Int. Cl. H10H 20/01; H10H 20/851; H10H 29/01; H10H 29/03; H10H 29/37; H10H 29/80

(52) U.S. Cl. CPC H10H 20/019; H10H 20/021; H10H 20/8515; H10H 29/012; H10H 29/03; H10H 29/37; H10H 29/8323

(57) ABSTRACT

A light-emitting device of an embodiment of the disclosure includes: a drive substrate; a plurality of light-emitting elements each having a first surface and a second surface, the first surface being opposed to the drive substrate, the second surface being on an opposite side to the first surface and being a light outputting surface, the plurality of light-emitting elements being disposed in an array on a side of one surface of the drive substrate and each including a compound semiconductor; and a growth substrate that is in contact with the second surface of each of the plurality of light-emitting elements, and forms an interface free of lattice mismatch with the compound semiconductor that configures each of the light-emitting elements.

### TECHNICAL FIELD

The present disclosure relates to a light-emitting device, a method of manufacturing the same, and an image display apparatus including the same.

### BACKGROUND ART

For example, PTL 1 discloses a method of manufacturing a solid-state imaging device in which a bonding strength is ensured by, when singulated heterogeneous semiconductor chips are bonded to a semiconductor substrate, preparing a highly planarized bonding surface, raising temperature while applying a load, and generating a covalent bond by a dehydration condensation reaction on an interface.

### CITATION LIST

### Patent Literature

PTL 1: International Publication No. WO 2019/087764

### SUMMARY OF THE INVENTION

Incidentally, in a light-emitting device formed by bonding heterogeneous semiconductor chips on a semiconductor substrate, for example, an improvement in manufacturing yield is demanded.

It is desirable to provide a light-emitting device, a method of manufacturing the light-emitting device, and an image display apparatus that each make it possible to improve a manufacturing yield.

A light-emitting device according to an embodiment of the present disclosure includes: a drive substrate; a plurality of light-emitting elements each having a first surface and a second surface, the first surface being opposed to the drive substrate, the second surface being on an opposite side to the first surface and being a light outputting surface, the plurality of light-emitting elements being disposed in an array on a side of one surface of the drive substrate and each including a compound semiconductor; and a growth substrate that is in contact with the second surface of each of the plurality of light-emitting elements, and forms an interface free of lattice mismatch with the compound semiconductor that configures each of the light-emitting elements.

A method of manufacturing a light-emitting device according to an embodiment of the present disclosure includes: epitaxially growing a compound semiconductor layer including an active layer on a growth substrate; singulating the compound semiconductor layer, together with the growth substrate, into a plurality of pieces; bonding the compound semiconductor layer having been singulated to a first support substrate with the growth substrate being opposed to the first support substrate; forming a plurality of light-emitting elements by separating the compound semiconductor layer; and causing a portion of the growth substrate to remain on a light outputting surface of each of the plurality of light-emitting elements by bonding the plurality of light-emitting elements to a second support substrate together with the growth substrate and thereafter grinding the growth substrate.

An image display apparatus according to an embodiment of the present disclosure includes a light-emitting device. Such a light-emitting device includes the light-emitting device according to the embodiment of the present disclosure described above.

In the light-emitting device of the embodiment of the present disclosure, the method of manufacturing the light-emitting device of the embodiment of the present disclosure, and the image display apparatus of the embodiment of the present disclosure, the growth substrate that forms the interface free of lattice mismatch is caused to remain on the light outputting surface of each of the plurality of light-emitting elements including the compound semiconductor. This prevents peeling of the light-emitting element.

### BRIEF DESCRIPTION OF DRAWINGS

FIG. 1 is a schematic cross-sectional diagram illustrating an example of a configuration of a light-emitting device according to a first embodiment of the present disclosure.

FIG. 2 is a schematic diagram illustrating an example of a planar configuration of the light-emitting device as a whole illustrated in FIG. 1.

FIG. 3 is an enlarged schematic diagram illustrating a portion of the planar configuration of the light-emitting device illustrated in FIG. 2.

FIG. 4 is a schematic diagram illustrating an example of a planar layout of a sapphire substrate on a light outputting surface of each of light-emitting elements illustrated in FIG. 1.

FIG. 5 is a schematic diagram illustrating another example of the planar layout of the sapphire substrate on the light outputting surface of each of the light-emitting elements illustrated in FIG. 1.

FIG. 6 is a schematic diagram illustrating an example of an optical path of outputted light in the light-emitting element illustrated in FIG. 1.

FIG. 7A is a schematic cross-sectional diagram for explaining an example of a process of manufacturing the light-emitting device illustrated in FIG. 1.

FIG. 7B is a schematic cross-sectional diagram illustrating a step following FIG. 7A.

FIG. 7C is a schematic cross-sectional diagram illustrating a step following FIG. 7B.

FIG. 7D is a schematic cross-sectional diagram illustrating a step following FIG. 7C.

FIG. 7E is a schematic cross-sectional diagram illustrating a step following FIG. 7D.

FIG. 7F is a schematic cross-sectional diagram illustrating a step following FIG. 7E.

FIG. 7G is a schematic cross-sectional diagram illustrating a step following FIG. 7F.

FIG. 7H is a schematic cross-sectional diagram illustrating a step following FIG. 7G.

FIG. 7I is a schematic cross-sectional diagram illustrating a step following FIG. 7H.

FIG. 7J is a schematic cross-sectional diagram illustrating a step following FIG. 7I.

FIG. 7K is a schematic cross-sectional diagram illustrating a step following FIG. 7J.

FIG. 8A is a schematic cross-sectional diagram illustrating a step following FIG. 7K.

FIG. 8B is a schematic cross-sectional diagram illustrating a step following FIG. 8A.

FIG. 8C is a schematic cross-sectional diagram illustrating a step following FIG. 8B.

FIG. 8D is a schematic cross-sectional diagram illustrating a step following FIG. 8C.

FIG. 8E is a schematic cross-sectional diagram illustrating a step following FIG. 8D.

FIG. 8F is a schematic cross-sectional diagram illustrating a step following FIG. 8E.

FIG. 8G is a schematic cross-sectional diagram illustrating a step following FIG. 8F.

FIG. 8H is a schematic cross-sectional diagram illustrating a step following FIG. 8G.

FIG. 8I is a schematic cross-sectional diagram illustrating a step following FIG. 8H.

FIG. 8J is a schematic cross-sectional diagram illustrating a step following FIG. 8I.

FIG. 8K is a schematic cross-sectional diagram illustrating a step following FIG. 8J.

FIG. 8L is a schematic cross-sectional diagram illustrating a step following FIG. 7K.

FIG. 8M is a schematic cross-sectional diagram illustrating a step following FIG. 8L.

FIG. 8N is a schematic cross-sectional diagram illustrating a step following FIG. 8M.

FIG. 8O is a schematic cross-sectional diagram illustrating a step following FIG. 8N.

FIG. 8P is a schematic cross-sectional diagram illustrating a step following FIG. 80.

FIG. 8Q is a schematic cross-sectional diagram illustrating a step following FIG. 8P.

FIG. 8R is a schematic cross-sectional diagram illustrating a step following FIG. 8Q.

FIG. 8S is a schematic cross-sectional diagram illustrating a step following FIG. 8R.

FIG. 8T is a schematic cross-sectional diagram illustrating a step following FIG. 8S.

FIG. 8U is a schematic cross-sectional diagram illustrating a step following FIG. 8T.

FIG. 8V is a schematic cross-sectional diagram illustrating a step following FIG. 8U.

FIG. 8W is a schematic cross-sectional diagram illustrating a step following FIG. 8V.

FIG. 9 is a schematic cross-sectional diagram illustrating an example of a configuration of a light-emitting device according to a second embodiment of the present disclosure.

FIG. 10 is an enlarged schematic diagram of a portion of a planar configuration of the light-emitting device illustrated in FIG. 9.

FIG. 11A is a schematic cross-sectional diagram for explaining an example of a process of manufacturing the light-emitting device illustrated in FIG. 10.

FIG. 11B is a schematic cross-sectional diagram illustrating a step following FIG. 11A.

FIG. 11C is a schematic cross-sectional diagram illustrating a step following FIG. 11B.

FIG. 11D is a schematic cross-sectional diagram illustrating a step following FIG. 11C.

FIG. 12 is a schematic cross-sectional diagram illustrating an example of a configuration of a light-emitting device according to Modification example 1 of the present disclosure.

FIG. 13 is an enlarged schematic diagram of a portion of a planar configuration of a light-emitting device according to Modification example 2 of the present disclosure.

FIG. 14 is a perspective diagram illustrating an example of a configuration of an image display apparatus according to an application example of the present disclosure.

FIG. 15 is a schematic diagram illustrating an example of a wiring layout of the image display apparatus illustrated in FIG. 14.

FIG. 16 is a perspective diagram illustrating an example of a configuration of an image display apparatus according to an application example of the present disclosure.

FIG. 17 is a perspective diagram illustrating a configuration of a mounting substrate illustrated in FIG. 16.

FIG. 18 is a perspective diagram illustrating a configuration of a unit substrate illustrated in FIG. 17.

FIG. 19 is a diagram illustrating an example of an image display apparatus according to an application example of the present disclosure.

### MODES FOR CARRYING OUT THE INVENTION

Hereinafter, an embodiment of the present disclosure will be described in detail with reference to the drawings. The following description is a specific example of the present disclosure, but the present disclosure is not limited to the following embodiment. Moreover, the present disclosure is not limited to arrangements, dimensions, dimensional ratios, and the like of each component illustrated in the drawings. It is to be noted that the description is given in the following order.
1. First Embodiment (Example in Which Sapphire Substrate is Patterned on Light Outputting Surface of Light-Emitting Element)
1-1. Configuration of Light-Emitting Device
1-2. Method of Manufacturing Light-Emitting Device
1-3. Workings and Effects
2. Second Embodiment
2-1. Configuration of Light-Emitting Device
2-2. Method of Manufacturing Light-Emitting Device
2-3. Workings and Effects
3. Modification Examples
3-1. Modification Example 1 (Another Example of Light-Emitting Device)
3-2. Modification Example 2 (Another Example of Light-Emitting Device)
4. Application Examples

### 1. FIRST EMBODIMENT

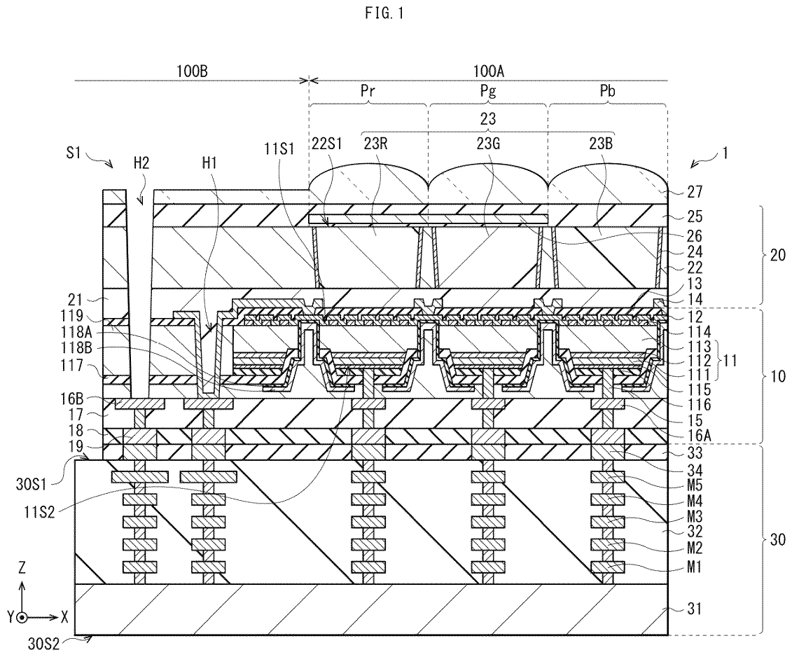

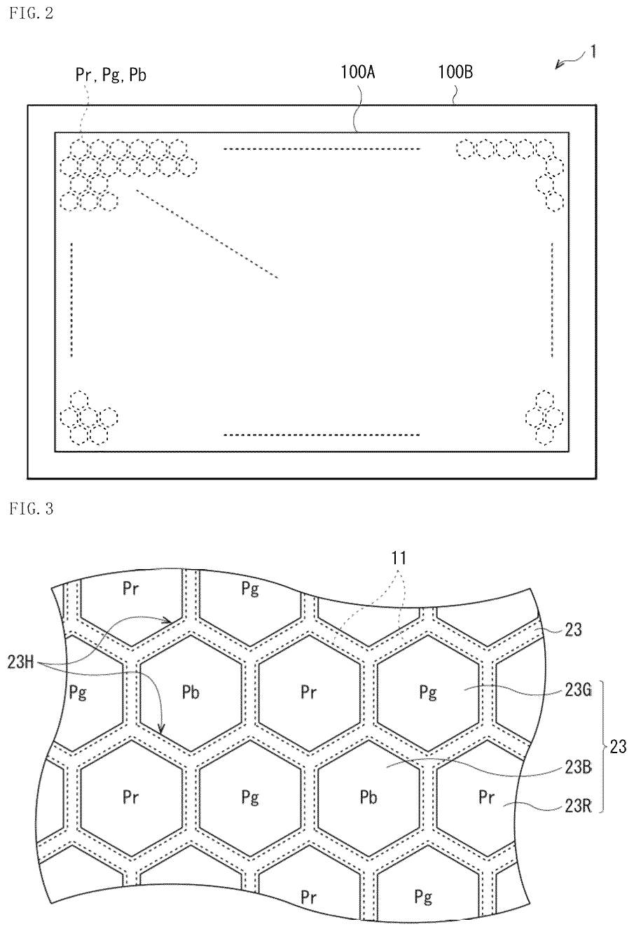

FIG. 1 schematically illustrates an example of a cross-sectional configuration of a light-emitting device (a light-emitting device 1) according to a first embodiment of the present disclosure. FIG. 2 schematically illustrates an example of a planar configuration of the light-emitting device 1 as a whole illustrated in FIG. 1. The light-emitting device 1 is suitably applicable to an image display apparatus (for example, an image display apparatus 100, see FIG. 14) that is referred to as what is called an LED display.

### 1-1. Configuration of Light-Emitting Device

The light-emitting device 1 has a display section 100A in which a plurality of light-emitting elements 11 is disposed in a two-dimensional array and a frame section 100B provided therearound. The light-emitting device 1 includes, for example, a drive substrate 30, a light-emitting section 10, and a wavelength conversion section 20. The drive substrate 30 has a front surface (a surface 30S1) and a back surface (a surface 30S2) that are opposed to each other. On a side of the surface 30S1 of the drive substrate 30, the light-emitting section 10 and the wavelength conversion section 20 are stacked in this order. The light-emitting section 10 includes the plurality of light-emitting elements 11 disposed in an array in the display section 100A. In the present embodiment, a sapphire substrate 114 is provided on a surface 11S1 to be a light outputting surface of the light-emitting element 11. The sapphire substrate 114 forms an interface free of lattice mismatch with a compound semiconductor layer 110 that configures the light-emitting elements 11. The sapphire substrate 114 is a growth substrate of the compound semiconductor layer 110, and is so patterned that an aperture ratio of the surface 11S1 is greater than or equal to 50%.

As described above, the light-emitting section 10 includes the plurality of light-emitting elements 11 disposed in a two-dimensional array in the display section 100A. Specifically, as illustrated in FIG. 3, for example, the plurality of light-emitting elements 11 has a substantially regular hexagonal shape and is disposed in, for example, a honeycomb shape. Formed on a side of the surface 11S1 of each of the plurality of light-emitting elements 11 are the sapphire substrate 114, an electrode layer 12, an insulating layer 13, and an extraction electrode 14, in this order. Formed on a side of the surface 11S2 of each of the plurality of light-emitting elements 11 are: an electrode layer 115, an insulating layer 116, and a protective layer 117 that are provided for each element; an insulating film 118A and a reflection film 118B that are continuous over the plurality of light-emitting elements 11; and an embedding layer 119 that embeds the plurality of light-emitting elements 11. Further formed on the side of the surface 11S2 of each of the plurality of light-emitting elements 11 are a plug 15 provided for each element, an insulating layer 17 including a pad 16A and a pad electrode 16B, and an insulating layer 18 including a pad 19 that electrically and physically bonds the light-emitting section 10 and the drive substrate 30 to each other, in this order.

The light-emitting element 11 corresponds to a specific example of a “light-emitting element” of the present disclosure. The light-emitting element 11 is a solid-state light-emitting element that emits light of a predetermined wavelength band from the surface 11S1, and is, for example, an LED (Light Emitting Diode) chip. The term “LED chip” refers to that which is cut out from a wafer used for a crystal growth, and is not of a package-type covered with a molded resin or the like. The LED chip has, for example, a size of greater than or equal to 5 μm and less than or equal to 100 μm, and is what is called a micro LED.

In the light-emitting element 11, a first conductivity-type layer 111, an active layer 112, and a second conductivity-type layer 113 are stacked in this order, and an upper surface of the second conductivity-type layer 113 serves as the light outputting surface (the surface 11S1).

The first conductivity-type layer 111 includes, for example, an n-type GaN-based semiconductor material. The active layer 112 has, for example, a multi-quantum-well structure in which InGaN and GaN are alternately stacked, and has a light-emitting region in the layer. From the active layer 112, for example, light in a blue band of greater than or equal to 430 nm and less than or equal to 500 nm is to be extracted. In addition to this, light having a wavelength corresponding to, for example, an ultraviolet region (ultraviolet light) may be extracted from the active layer 112. The second conductivity-type layer 113 includes, for example, a p-type GaN-based semiconductor material.

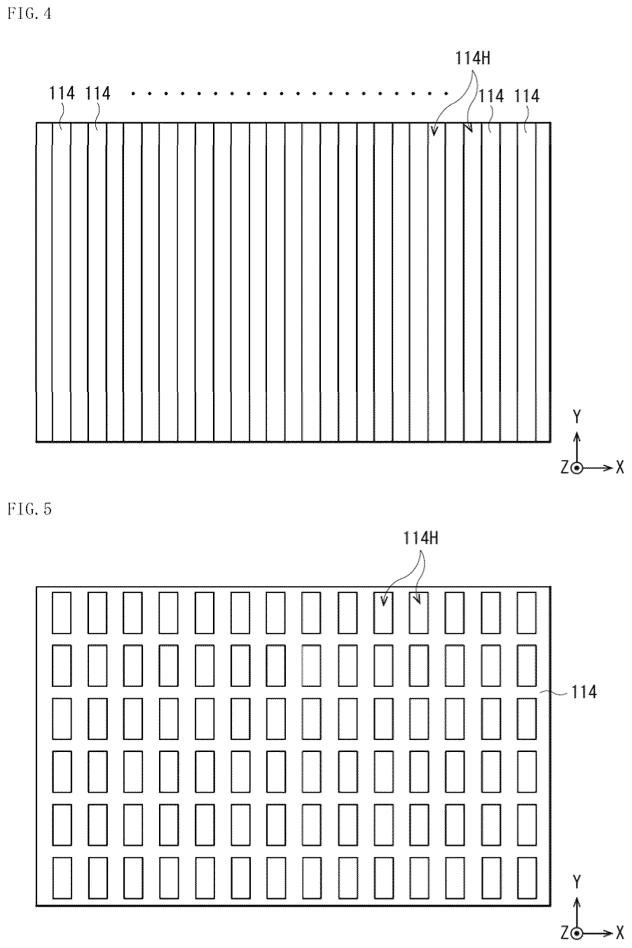

The sapphire substrate 114 is patterned on the surface 11S1 of the light-emitting element 11. The sapphire substrate is a growth substrate in allowing crystal growth of the compound semiconductor layer 110 including the first conductivity-type layer 111, the active layer, and the second conductivity-type layer 113. Accordingly, the sapphire substrate forms the interface free of lattice mismatch with the compound semiconductor layer 110 (specifically, the second conductivity-type layer 113). For example, as illustrated in FIG. 4, the sapphire substrate 114 is open in a stripe shape. Alternatively, as illustrated in FIG. 5, the sapphire substrate 114 is open in a grid shape. In both cases, the aperture ratio of the surface 11S1 is greater than or equal to 50% in view of light-extraction efficiency from the surface 11S1.

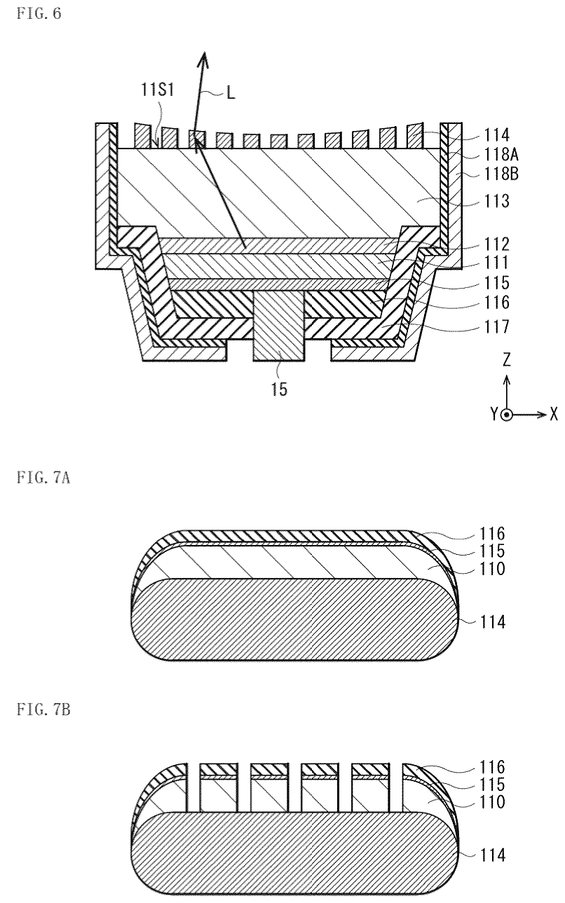

The sapphire substrate 114 patterned on the surface 11S1 of the light-emitting element 11 has a thickness of, for example, greater than or equal to 500 nm and less than or equal to 6 μm. The sapphire substrate 114 may have a uniform thickness in a plane of the surface 11S1, or, for example, as illustrated in FIG. 6, the sapphire substrate 114 may be formed into a concave shape in which a thickness of a middle part in the plane of the surface 11S1 is smaller than a thickness of a peripheral part in the plane of the surface 11S1. On a front surface and a side surface of the sapphire substrate 114 patterned on the surface 11S1 of the light-emitting element 11, the electrode layer 12 including, for example, ITO is formed. The sapphire substrate 114 has a refractive index of about 1.6, and the electrode layer 12 (indium tin oxide (ITO)) has a refractive index of about 2.0. By forming the sapphire substrate 114 into the concave shape as described above, a lens effect is obtainable with respect to light emission from the active layer 112. Specifically, as illustrated in FIG. 6, light L outputted from the active layer in an oblique direction is extracted in a direction substantially perpendicular to the surface 11S1 owing to a difference in refractive index at an interface between the sapphire substrate 114 and the electrode layer 12, thereby improving luminance.

The electrode layer 12 serves as a common electrode with respect to the plurality of light-emitting elements 11, and is formed continuously on the surface 11S1 of each of plurality of light-emitting elements 11 and on the upper surface and the side surface of the sapphire substrate 114 patterned on the surface 11S1. The electrode layer 12 is in ohmic contact with the second conductivity-type layer 113, and includes a transparent electrode material such as ITO, indium zinc oxide (IZO), tin oxide (SnO), or TiO.

The insulating layer 13 embeds irregularities formed above the plurality of light-emitting elements 11. The insulating layer 13 includes, for example, silicon oxide (SiO), silicon nitride (SiN), or the like.

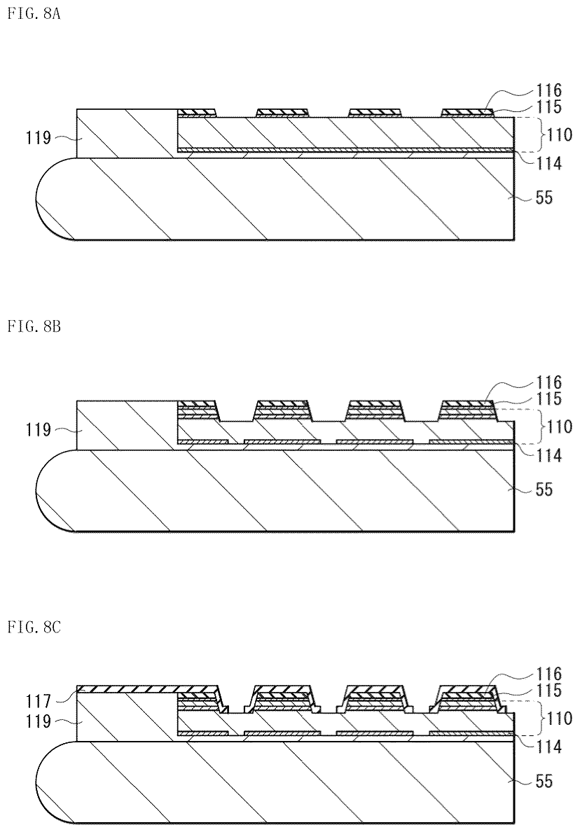

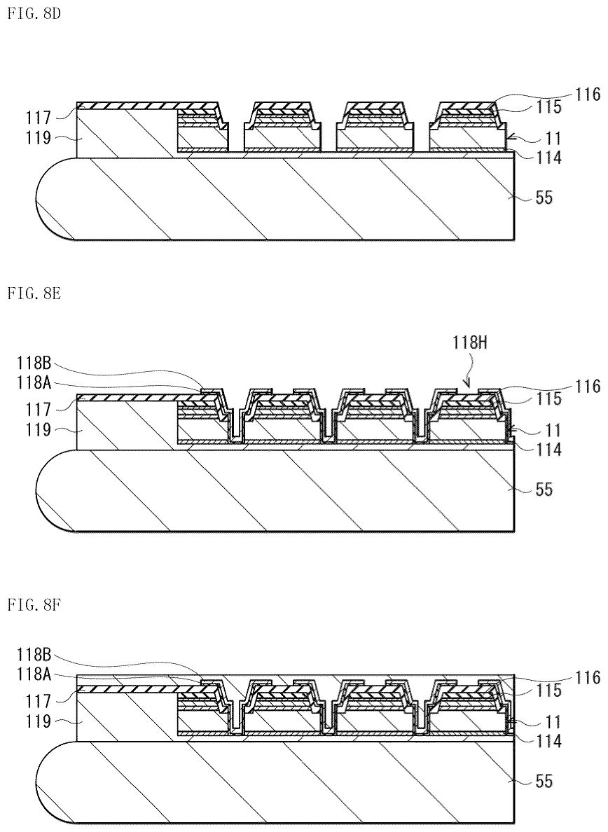

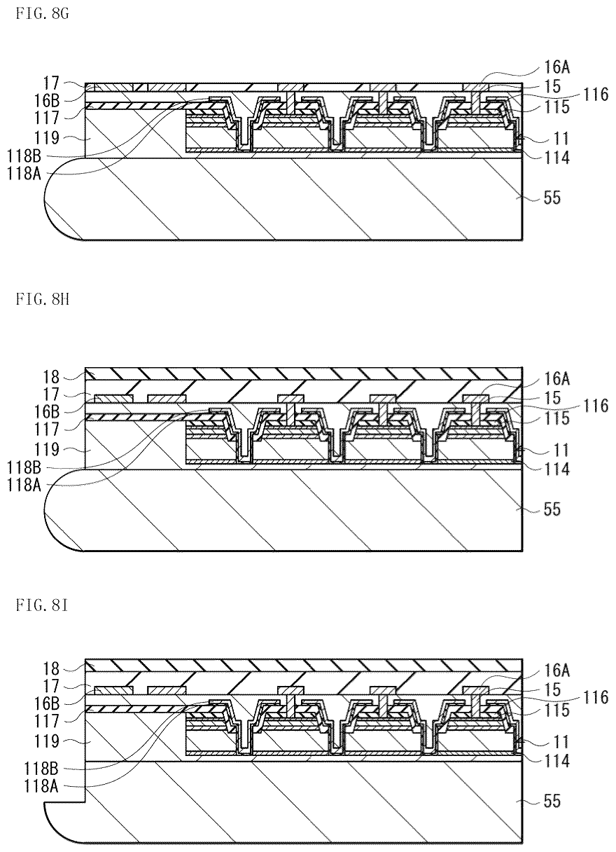

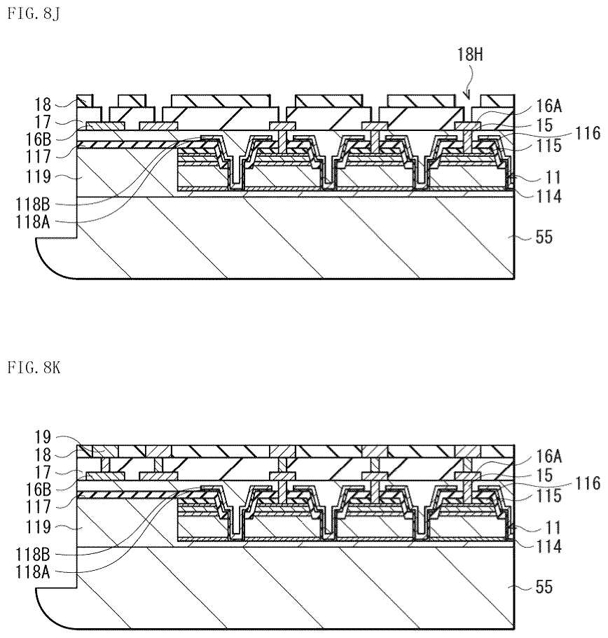

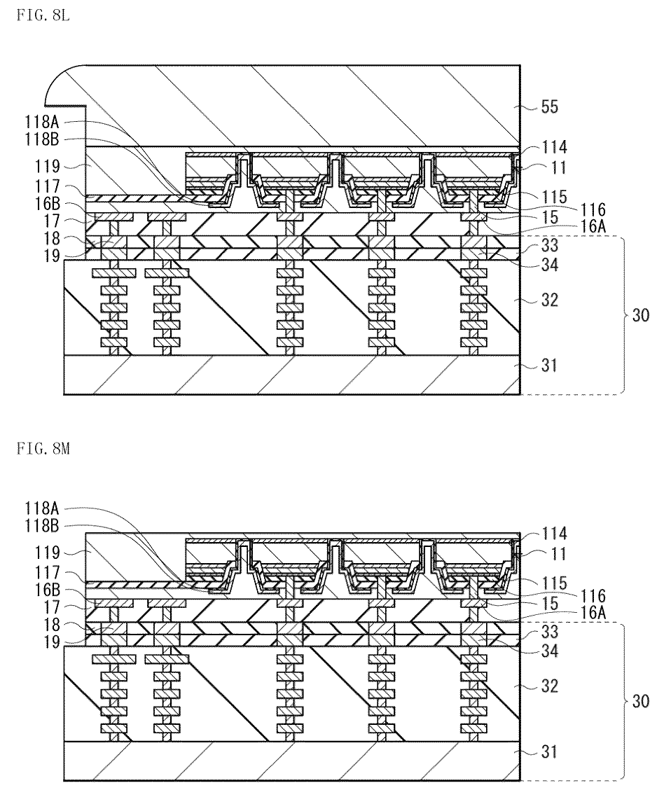

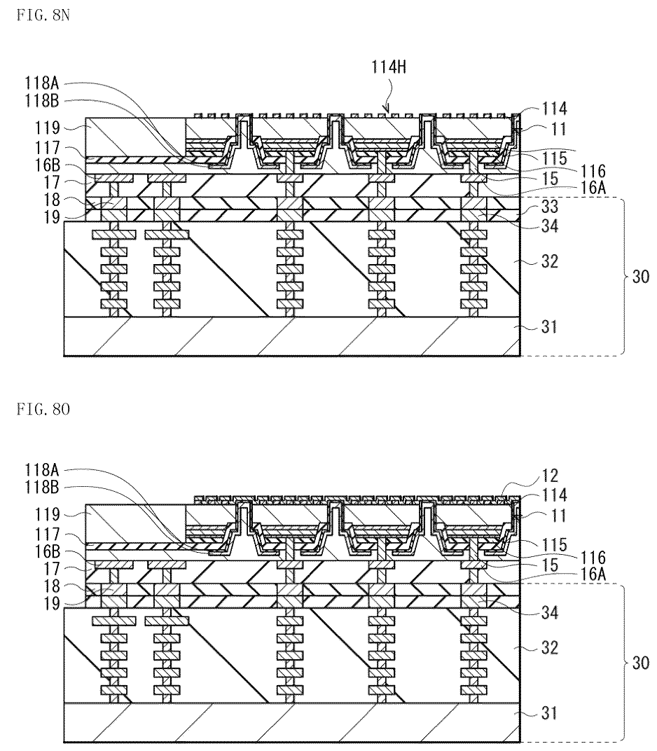

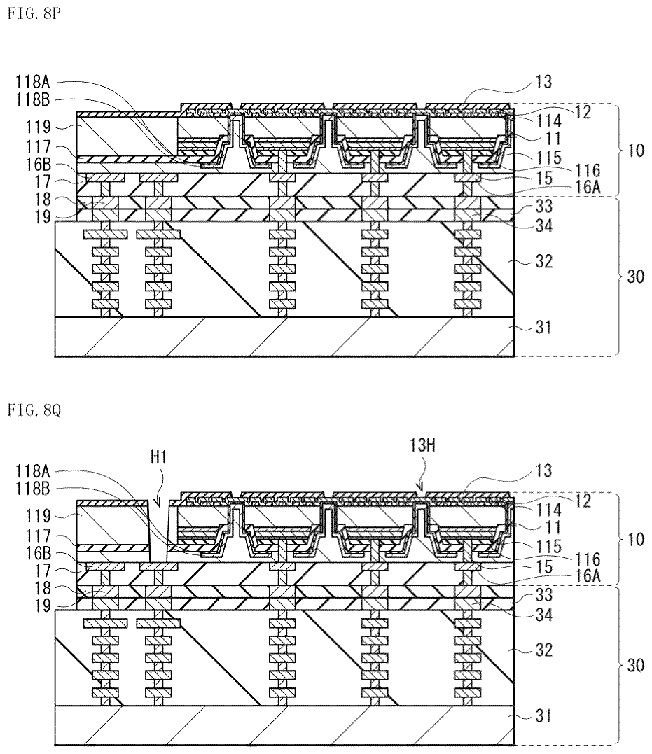

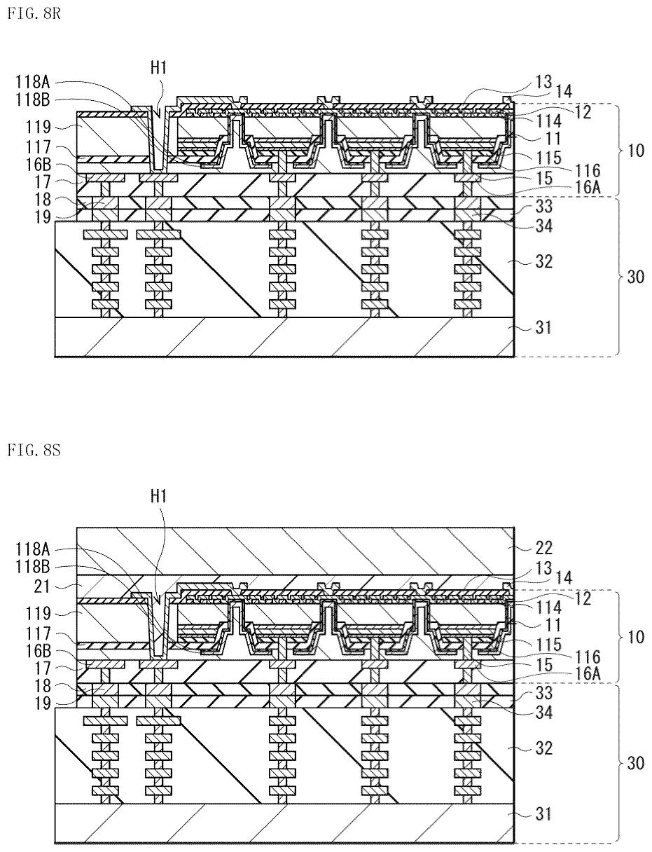

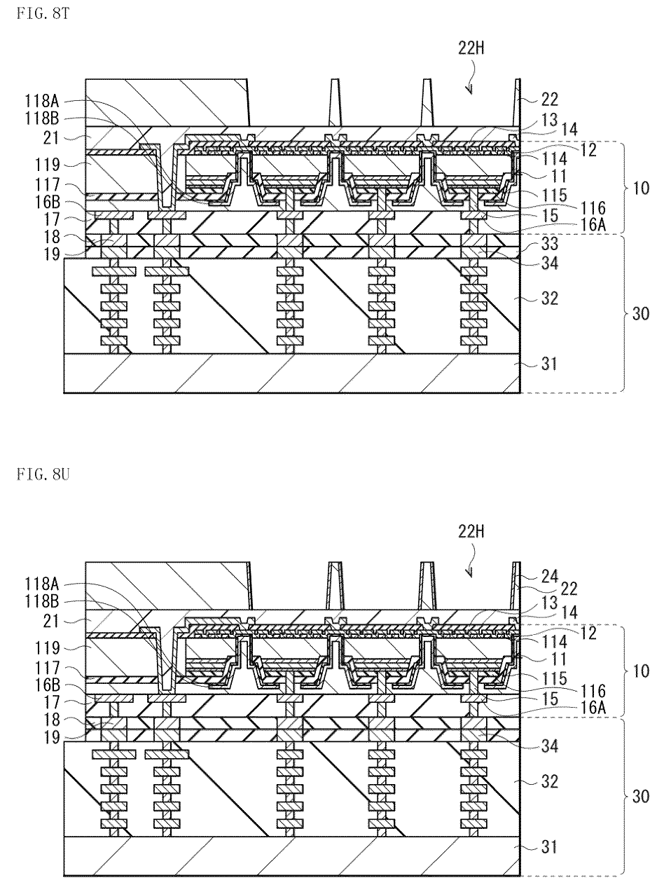

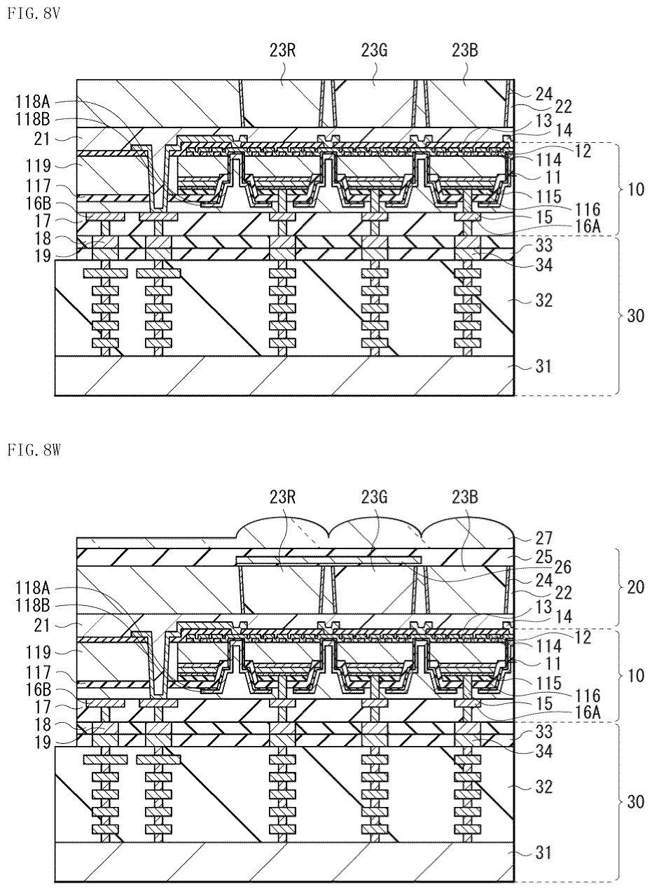

The extraction electrode 14 applies a voltage to the second conductivity-type layer 113 of each of the plurality of light-emitting elements 11, and is electrically coupled to the electrode layer 12 via, for example, an opening 13H (see FIG. 8Q) provided in the insulating layer 13 between adjacent light-emitting elements 11. In the display section 100A, the extraction electrode 14 is formed continuously between the adjacent light-emitting elements 11 so as to keep away from the surface 11S1 of each of the plurality of light-emitting elements 11 disposed in a honeycomb shape, for example, and extends to a portion of the frame section 100B. The extraction electrode 14 formed in the frame section 100B is electrically coupled to the pad electrode 16B via an opening H1 that passes through the insulating layer 13, the embedding layer 119, and the protective layer 117. The extraction electrode 14 includes, for example, a multi-layer film (Ti/Al) of titanium (Ti) and aluminum (Al), or a multi-layer film (Cr/Au) of chromium (Cr) and gold (Au).

The electrode layer 115 is formed on a lower surface (the surface 11S2) of the first conductivity-type layer 111 of the light-emitting element 11. The electrode layer 115 is in ohmic contact with the first conductivity-type layer 111, and includes a transparent conductive material such as a multi-layer film (Ni/Au) of nickel (Ni) and gold (Au), or ITO.

The insulating layer 116 is provided on the electrode layer 115. The insulating layer 116 includes, for example, silicon oxide (SiO), silicon nitride (SiN), or the like.

The light-emitting element 11 has, on a side of the drive substrate 30, a mesa shape that includes the first conductivity-type layer 111, the active layer 112, and a portion of the second conductivity-type layer 113. The surface 11S2 of the light-emitting element 11 and respective side surfaces of the first conductivity-type layer 111, the active layer 112, and a portion of the second conductivity-type layer 113, which are processed into the mesa shape, are covered with the protective layer 117. The protective layer 117 includes, for example, silicon oxide (SiO), silicon nitride (SiN), or the like.

Furthermore, the protective layer 117 and a side surface of the second conductivity-type layer 113 exposed above the protective layer 117 are covered with a stacked film of the insulating film 118A and the reflection film 118B. The stacked film is continuously formed over the plurality of light-emitting elements 11. The stacked film has an opening 118H on the side of the surface 11S2 of the light-emitting element 11, and the plug 15 is formed in the opening 118H.

The embedding layer 119 embeds the plurality of light-emitting elements 11 and forms a flat front surface and a flat back surface of the light-emitting section 10. The embedding layer 119 includes, for example, silicon oxide (SiO), silicon nitride (SiN), or the like.

The plug 15 applies a voltage to the first conductivity-type layer 111 of each of the plurality of light-emitting elements 11. The plug 15 includes, for example, copper (Cu), aluminum (Al), tungsten (W), silver (Ag), an alloy thereof, or the like.

The insulating layer 17 is provided on the side of the drive substrate 30 of the embedding layer 119. Formed in the insulating layer 17 are a plurality of pads 16A respectively provided for the light-emitting elements 11A in the display section 100A, a plurality of pad electrodes 16B provided in the frame section 100B, and vias. The insulating layer 17 includes, for example, silicon oxide (SiO), silicon nitride (SiN), or the like. The pad 16A, the pad electrode 16B, and the via each include, for example, copper (Cu), aluminum (Al), tungsten (W), silver (Ag), an alloy thereof, or the like.

In addition, provided on the side of the drive substrate 30 of the insulating layer 17 are the insulating layer 18 that forms a bonding surface with the drive substrate 30 and the pad 19 embedded in the insulating layer 18. The insulating layer 18 includes, for example, silicon oxide (SiO), silicon nitride (SiN), or the like. The pad 19 includes, for example, copper (Cu).

The wavelength conversion section 20 is provided on a side of a light extraction surface S1 of the light-emitting section 10. The wavelength conversion section 20 includes a planarization layer 21, a partition layer 22 having, for example, an opening 22H for each of the light-emitting elements 11, and a wavelength conversion layer 23 formed in the opening 22H. A reflection film 24 is further provided between the partition layer 22 and the wavelength conversion layer 23. A protective layer 25 is further provided on a side of the light outputting surface 22S1 of the wavelength conversion layer 23, and a wavelength selection layer 26 is further provided in the protective layer 25. An on-chip lens layer 27 is further provided on the protective layer 25.

The planarization layer 21 is for planarizing a surface, of the light-emitting section 10, on the side of the light extraction surface S1. The planarization layer 21 includes, for example, silicon oxide (SiO), silicon nitride (SiN), or the like.

When the light-emitting device 1 is applied to the image display apparatus 100, the partition layer 22 suppresses an occurrence of color mixing due to light leakage between sub-pixels (a red pixel Pr, a green pixel Pg, and a blue pixel Pb) of adjacent RGB. The partition layer 22 has, for example, a honeycomb structure. Specifically, as illustrated in FIG. 3, the partition layer 22 has, for example, the opening 22H having a substantially regular hexagonal shape for each of the plurality of light-emitting elements 11 disposed in an array. The opening 22H has, for example, an inclined surface of less than 90° with respect to a surface 20S2, of the wavelength conversion section 20, that is on an opposite side to a surface 20S1 of the wavelength conversion section 20 in a cross-sectional view. In other words, the partition layer 22 has a forward tapered shape between adjacent color pixels Pr, Pg, and Pb in a cross-sectional view. The partition layer 22 preferably includes a material having high heat conductivity and high electric conductivity, and includes, for example, a metal material such as copper (Cu), aluminum (Al), gold (Au), nickel (Ni), or platinum (Pt).

The wavelength conversion layer 23 corresponds to a specific example of a “wavelength conversion layer” of the present disclosure. The wavelength conversion layer 23 is for converting a wavelength of light to be emitted from each of the plurality of light-emitting elements 11 into a desired wavelength (for example, red (R)/green (G)/blue (B)) and outputting the light, and is formed in the opening 22H provided above each of the light-emitting elements 11. Specifically, the red pixel Pr is provided with a red wavelength conversion layer 23R that converts light outputted from the light-emitting element 11 into red band light (red light), the green pixel Pg is provided with a green wavelength conversion layer 23G that converts light outputted from the light-emitting element 11 into green band light (green light), and the blue pixel Pb is provided with a blue wavelength conversion layer 23B that converts light outputted from the light-emitting element 11 into blue band light (blue light).

It is possible to form each of the wavelength conversion layers 23R, 23G, and 23B using quantum dots corresponding to each color. Specifically, in a case where the red light is to be obtained, the quantum dots are selectable from, for example, InP, GaInP, InAsP, CdSe, CdZnSe, CdTeSe, CdTe, and the like. In a case where the green light is to be obtained, the quantum-dots are selectable from, for example, InP, GaInP, ZnSeTe, ZnTe, CdSe, CdZnSe, CdS, CdSeS, and the like. In a case where the blue light is to be obtained, the quantum-dots are selectable from, for example, ZnSe, ZnTe, ZnSeTe, CdSe, CdZnSe, CdS, CdZnS, CdSeS, and the like. It is to be noted that, in the case where the blue light is to be outputted from the light-emitting element 11 as described above, the blue wavelength conversion layer 23B may include a resin layer having a light-transmitting property.

The reflection film 24 is provided on a side surface of the opening 22H for efficiently extracting the respective pieces of color light outputted from the light-emitting elements 11 and converted in the respective wavelength conversion layers 23R, 23G, and 23B from a light extraction surface (the surface 22S1) of the wavelength conversion layer 23. The reflection film 24 includes a metal material having a light-reflecting property. Examples of the metal material included in the reflection film 24 include a metal having a high reflectance in a visible light region. Specific examples of the material include silver (Ag), aluminum (Al), copper (Cu), gold (Au), platinum (Pt), rhodium (Rh), and an alloy thereof.

It is to be noted that the reflection film 24 does not necessarily have to be formed in a case where the partition layer 22 includes the above-described metal material having a light-reflecting property.

The protective layer 25 is for protecting a surface of the light-emitting device 1, and includes, for example, silicon oxide (SiO), silicon nitride (SiN), or the like.

In the protective layer 25, the wavelength selection layer 26 is provided over the red pixel Pr and the green pixel Pg. The wavelength selection layer 26 selectively reflects, for example, the light in the blue band (the blue light), thereby improving chromatic purity of the red light extracted from the red pixel Pr and chromatic purity of the green light extracted from the green pixel Pg.

The on-chip lens layer 27 is provided so as to cover the entire surface of the display section 100A and the frame section 100B. The on-chip lens layer 27 is configured by a material having a light-transmitting property. For example, the on-chip lens layer 27 is configured by a single-layer film including any one of silicon oxide (SiO), silicon nitride (SiN), silicon oxynitride (SiCN), or the like, or a stacked film including two or more thereof.

The frame section 100B has an opening H2 that passes through the on-chip lens layer 27, the protective layer 25, the partition layer 22, the planarization layer 21, the insulating layer 13, the embedding layer 119, and the protective layer 117, and reaches the pad electrode 18B. The pad electrode 18B exposed at a bottom part of the opening H2 is used as an electrode to be coupled to an outside.

The drive substrate 30 is provided with a driving circuit or the like that controls driving of the plurality of light-emitting elements 11 disposed in the display section 100A. The drive substrate 30 includes: a support substrate 31; an interlayer insulating layer 32 that is provided on the support substrate 31 and includes a plurality of wiring layers (e.g., wiring layers M1, M2, M3, M4, and M5) and a via that electrically couples the wiring layers; an insulating layer 33 forming a bonding surface with the light-emitting section 10; and a pad 34 embedded in the insulating layer 33.

The interlayer insulating layer 32 includes, for example, silicon oxide (SiO), silicon nitride (SiN), or the like.

The wiring layers M1, M2, M3, M4, and M5, and the via that electrically couples the wiring layers each include, for example, copper (Cu), aluminum (Al), tungsten (W), silver (Ag), or an alloy thereof. The insulating layer 33 includes, for example, silicon oxide (SiO), silicon nitride (SiN), or the like. The pad 35 includes, for example, copper (Cu).

### 1-2. Method of Manufacturing Light-Emitting Device

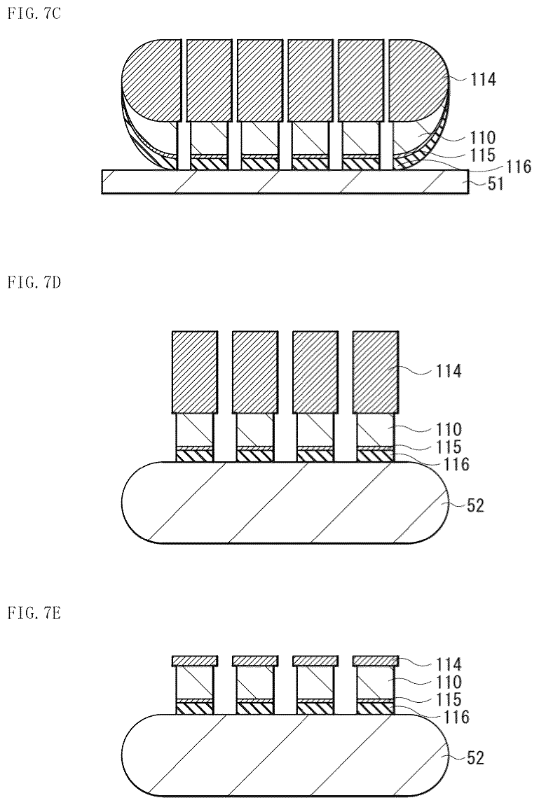

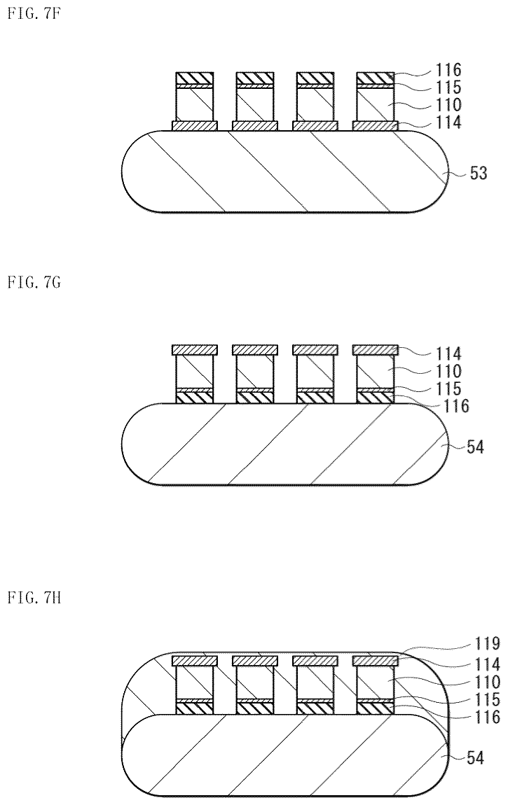

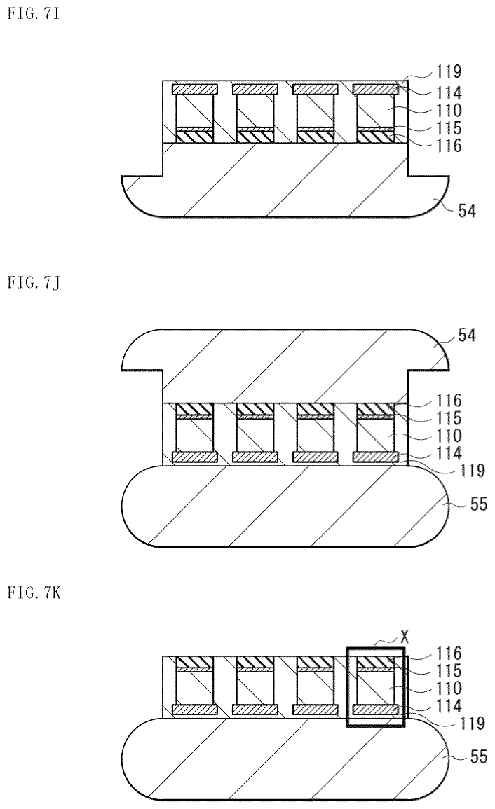

The light-emitting device 1 of the present embodiment is manufacturable, for example, as follows. FIGS. 7A to 7K and FIGS. 8A to 8W illustrate exemplary manufacturing steps of the light-emitting device 1.

First, as illustrated in FIG. 7A, the compound semiconductor layer 110 is formed by epitaxial crystallization growth using the sapphire substrate 114 as a growth substrate, for example, using a method such as a metal organic chemical vapor deposition (MOCVD) method or a molecular beam epitaxy (MBE) method. Thereafter, the electrode layer 115 and the insulating layer 116 are formed on the compound semiconductor layer 110 by, for example, a chemical vapor deposition (CVD) method. Thereafter, a surface of the insulating layer 116 is planarized, for example, by chemical mechanical polishing (CMP).

Thereafter, as illustrated in FIG. 7B, the insulating layer 116, the electrode layer 115, and the compound semiconductor layer 110 are etched and patterned using, for example, a photolithography technique. Thereafter, as illustrated in FIG. 7C, the sapphire substrate 114 is so transferred that the insulating layer 116 faces a support substrate 51, following which the sapphire substrate 114 is cleaved and singulated. Thereafter, as illustrated in FIG. 7D, each of the singulated sapphire substrates 114 is so bonded that the insulating layer 116 faces a transfer substrate 52.

Thereafter, as illustrated in FIG. 7E, the sapphire substrate 114 is thinned, for example, to have a thickness of 500 nm by, for example, grinding polishing. Thereafter, as illustrated in FIG. 7F, a reversing substrate 53 is bonded to a side of the sapphire substrate 114 and reversed, and the transfer substrate 52 is peeled off. Thereafter, the insulating layer 116 is re-planarized by, for example, CMP, following which, as illustrated in FIG. 7G, the insulating layer 116 is bonded to a support substrate 54.

Thereafter, as illustrated in FIG. 7H, the embedding layer 119 is formed and planarized on the support board 54 by, for example, a CVD method, following which, as illustrated in FIG. 7I, end parts of the support substrate 54 are trimmed. Thereafter, as illustrated in FIG. 7J, the embedding layer 119 is bonded to a support substrate 55 by, for example, plasma bonding, following which the support substrate 54 is peeled off. Hereinafter, the inside of a frame X, in an enlarged manner, indicated in FIG. 7K will be described.

First, as illustrated in FIG. 8A, the insulating layer 116 and the electrode layer 115 are etched and patterned using, for example, a photolithography technique. Thereafter, as illustrated in FIG. 8B, a portion of the compound semiconductor layer is etched using, for example, a photolithography technique to form a mesa structure including the first conductivity-type layer 111, the active layer 112, and a portion of the second conductivity-type layer 113.

Thereafter, an AlO film is formed by, for example, an atomic layer deposition (ALD) method, over an upper surface of the insulating layer 116, a side surface of the insulating layer 116, the electrode layer 115, and the mesa structure including the first conductivity-type layer 111, the active layer 112, and the second conductivity-type layer 113, and a bottom surface, following which a SiN film is further formed by, for example, a CVD method. Thereafter, the SiN film is etched using, for example, a photolithography technique to form the protective layer 117 as a sidewall on an upper surface and a side surface of the mesa structure, as illustrated in FIG. 8C.

Thereafter, as illustrated in FIG. 8D, the second conductivity-type layer 113 and the sapphire substrate 114 exposed from the protective layer 117, for example, are cut off to form the plurality of light-emitting elements 11 using, for example, a photolithography technique. Thereafter, an AIO film is formed on an upper surface of the protective layer 117 and a side surface of the exposed light-emitting element 11 by, for example, an ALD method. Thereafter, as illustrated in FIG. 8E, the insulating film 118A and the reflection film 118B are sequentially formed by, for example, a CVD method, following which the opening 118H is formed on the upper surface of the mesa structure.

Thereafter, as illustrated in FIG. 8F, the the embedding layer 119 is formed and planarized again by, for example, a CVD method. Thereafter, as illustrated in FIG. 8G, the plug 15 for each light-emitting element 11 and the insulating layer 17 in which the plurality of pads 16A and the plurality of pad electrodes 16B are embedded are formed. Thereafter, as illustrated in FIG. 8H, the insulating layer 17 is thickened and the insulating layer 18 is formed on the insulating layer 17. Thereafter, as illustrated in FIG. 8I, an end part is trimmed.

Thereafter, as illustrated in FIG. 8J, the opening 18H is formed on each of the pads 16A and the pad electrodes 16B. Thereafter, as illustrated in FIG. 8K, the plurality of pads 19 are formed by embedding, for example, Cu in each of the openings 18H. Thereafter, the surfaces of the insulating layer 18 and the plurality of pads 19 are polished by, for example, CMP, to planarize the bonding surface with the drive substrate 30.

Thereafter, as illustrated in FIG. 8L, the plurality of pads 34 of the drive substrate 30 that has been separately formed and the plurality of pads 19 are bonded to each other by Cu-Cu bonding, following which the support substrate 55 is peeled off as illustrated in FIG. 8M. Thereafter, as illustrated FIG. 8N, the sapphire substrate 114 is patterned using, for example, a photolithography technique to form an opening 114H. Thereafter, as illustrated in FIG. 80, an ITO film is formed by, for example, a CVD method, following which an ITO film is patterned using, for example, a photolithography technique to form the electrode layer 12.

Thereafter, as illustrated in FIG. 8P, the insulating layer 13 is formed by, for example, a CVD method, following which, as illustrated in FIG. 8Q, the opening H1 reaching the opening 13H and the pad electrode 16B is formed between the light-emitting elements 11 that are adjacent to each other using, for example, a photolithography technique. Thereafter, for example, a stacked film of Ti/W is formed by, for example, a CVD method, following which the stacked film is patterned using, for example, a photolithography technique to form the extraction electrode 14 as illustrated in FIG. 8R.

Thereafter, as illustrated in FIG. 8S, the planarization layer 21 and the partition layer 22 are sequentially formed by, for example, a CVD method. Thereafter, as illustrated in FIG. 8T, the opening 22H is formed in an upper portion of the partition layer 22 of each of the light-emitting elements 11 using, for example, a photolithography technique. Thereafter, as illustrated in FIG. 8U, an Al film is formed on an upper surface of the partition layer 22 and a side surface and a bottom surface of the opening 22H by, for example, a CVD method. Thereafter, the Al film formed on the upper surface of the partition layer 22 and the bottom surface of the opening 22H is removed by etch-back to form the reflection film 24 on the side surface of the opening 22H.

Thereafter, as illustrated in FIG. 8V, the wavelength conversion layers 23 (23R, 23G, and 23B) of the respective colors are each formed in corresponding one of the openings 22H by a coating method such as an ink jet method. Thereafter, as illustrated in FIG. 8W, the protective layer 25 containing the wavelength selection layer 26 is formed on the partition layer 22 and the wavelength conversion layer 23, following which the on-chip lens layer 27 is bonded thereto. Thus, the light-emitting device 1 illustrated in FIG. 1 is completed.

### 1-3. Workings and Effects

In the light-emitting device 1 of the present embodiment, the sapphire substrate 114 is caused to remain on the light outputting surface (the surface 11S1) of each of the plurality of light-emitting elements. The sapphire substrate 114 is a growth substrate of the compound semiconductor layer 110 that configures the plurality of light-emitting elements 11 in the manufacturing process, and forms the interface free of lattice mismatch with the compound semiconductor layer 110. This prevents peeling of the light-emitting element 11. This will be described below.

In recent years, a high-definition image display apparatus using a light-emitting device having a micro LED using gallium nitride (GaN) as a light source has become popular. In a process of manufacturing such a light-emitting device, there is a step of joining singulated GaN chips side by side on a substrate, and performing laser lift-off on a sapphire substrate that is a growth substrate. In this case, in order to ensure a bonding strength between the substrate and the GaN chip, for example, a method is considered in which a dehydration-condensation reaction is caused to occur at an interface between the GaN chip and the substrate by raising temperature while applying a load, thereby generating a covalent bond.

However, because the GaN chip has an internal stress, the GaN chip lifts up when the sapphire substrate is removed, and in a step that follows, a phenomenon in which the GaN chip is peeled off from the substrate occurs. Cracks or the like can occur in the peeled GaN chip, which makes it difficult to fabricate an LED device.

In contrast, in the present embodiment, the sapphire substrate including the singulated compound semiconductor layer 110 is bonded to the transfer substrate 52, following which the sapphire substrate 114 is thinned by, for example, grinding polishing, and is etched and patterned to cause the sapphire substrate 114 to remain on the surface 11S1 of the light-emitting element 11. As a result, for example, the compound semiconductor layer 110 on the transfer substrate 52 or the support substrate 54 is reinforced, and peeling by the internal stress is suppressed.

Therefore, it is possible to improve a manufacturing yield of each of the light-emitting device 1 of the present embodiment and the image display apparatus 100 including the light-emitting device 1 of the present embodiment.

Next, description is given of a second embodiment, Modification examples 1 and 2, and application examples of the present disclosure. It is to be noted that components corresponding to those of the light-emitting device 1 according to the above-described first embodiment are denoted with the same reference numerals, and descriptions thereof are omitted.

### 2. SECOND EMBODIMENT

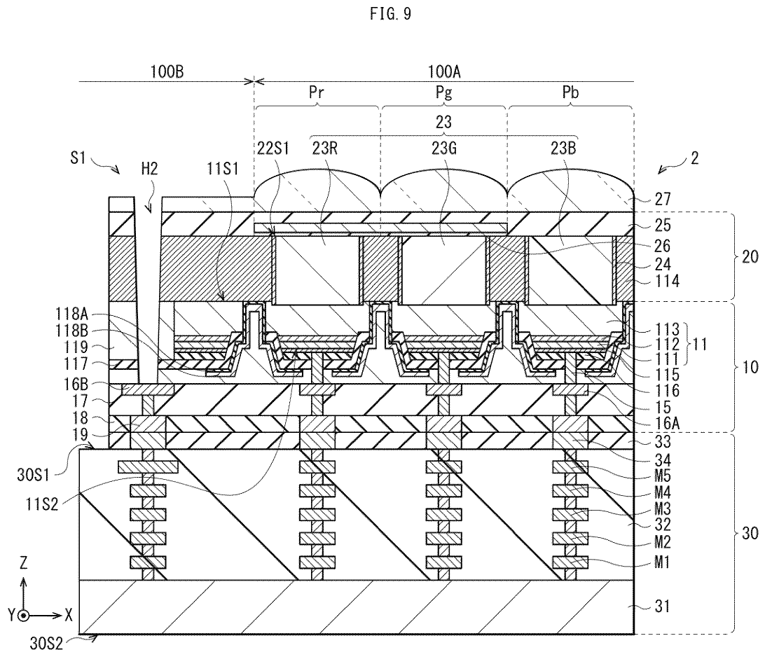

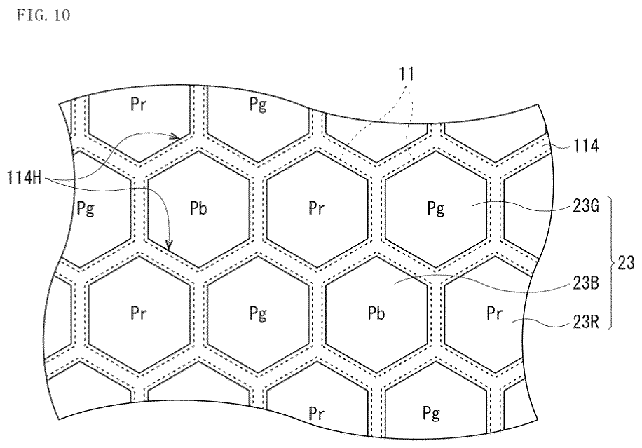

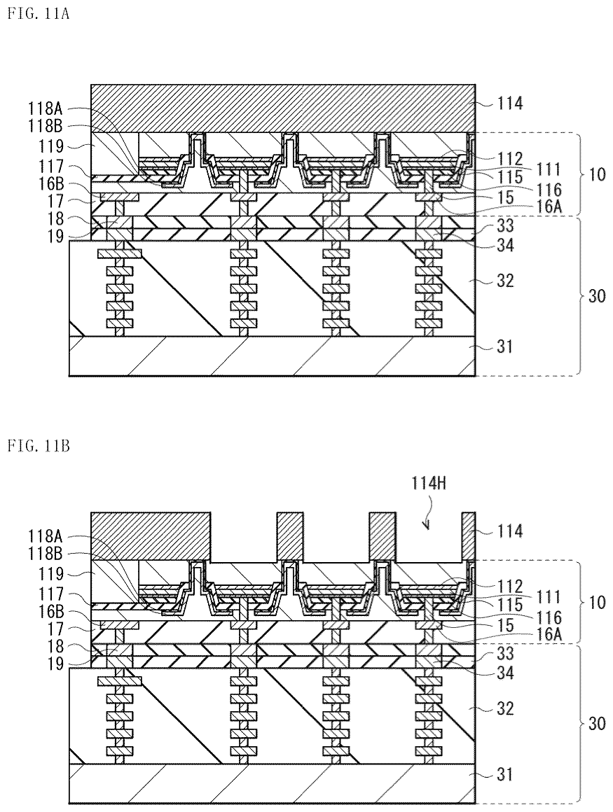

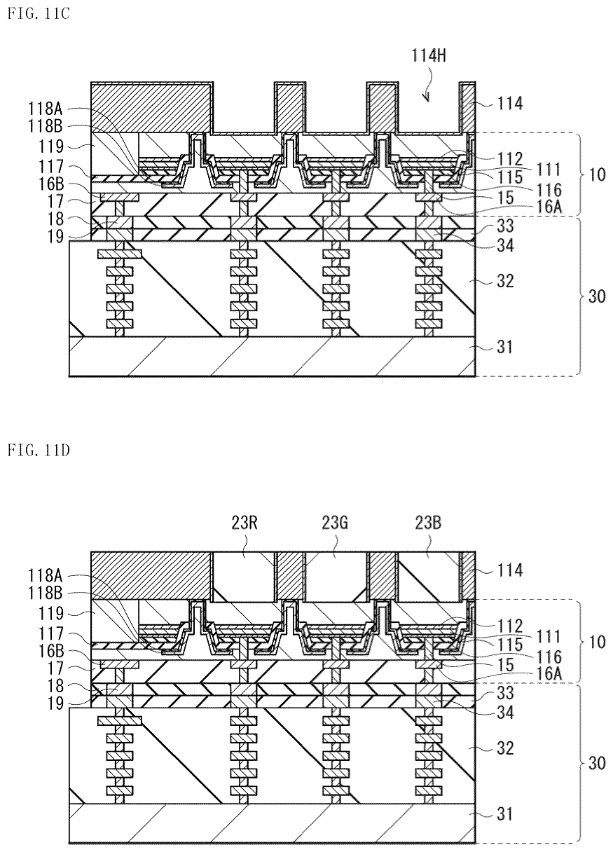

FIG. 9 schematically illustrates an example of a cross-sectional configuration of a light-emitting device (a light-emitting device 2) according to a second embodiment of the present disclosure. FIG. 10 schematically illustrates, in an enlarged manner, a portion of a planar configuration of the light-emitting device 2 illustrated in FIG. 9. As with the light-emitting device 1 of the above-described first embodiment, the light-emitting device 2 is suitably applicable to an image display apparatus (for example, an image display apparatus 100, see FIG. 14) that is referred to as what is called an LED display.

### 2-1. Configuration of Light-Emitting Device

The light-emitting device 2 has the display section 100A in which the plurality of light-emitting elements 11 is disposed in a two-dimensional array and the frame section 100B provided therearound, as in the light-emitting device 1 of the above-described first embodiment. The light-emitting device 2 includes, for example, the drive substrate 30, the light-emitting section 10, and the wavelength conversion section 20. The drive substrate 30 has the front surface (the surface 30S1) and the back surface (the surface 30S2) that are opposed to each other. On the side of the surface 30S1 of the drive substrate 30, the light-emitting section 10 and the wavelength conversion section 20 are stacked in this order. The light-emitting section 10 includes the plurality of light-emitting elements 11 disposed in an array in the display section 100A. In the present embodiment, the sapphire substrate 114, which is a growth substrate of the compound semiconductor layer 110 that configures the light-emitting elements 11, is provided as a partition layer in the wavelength conversion section 20. The partition layer partitions a space on a side of the light extraction surface S1 of each of the plurality of light-emitting elements 11 disposed in an array. The space is partitioned for each of the light-emitting elements 11.

The light-emitting section 10 includes the plurality of light-emitting elements 11 disposed in a two-dimensional array in the display section 100A, as in the above-described first embodiment. Specifically, as illustrated in FIG. 3, for example, the plurality of light-emitting elements 11 has a substantially regular hexagonal shape and is disposed in, for example, a honeycomb shape. Formed on the side of the surface 11S2 of each of the plurality of light-emitting elements 11 are: the electrode layer 115, the insulating layer 116, and the protective layer 117 that are provided for each element; the insulating film 118A and the reflection film 118B that are continuous over the plurality of light-emitting elements 11; and the embedding layer 119 that embeds the plurality of light-emitting elements 11. Further formed on the side of the surface 11S2 of each of the plurality of light-emitting elements 11 are the plug 15 provided for each element, the insulating layer 17 including the pad 16A and the pad electrode 16B, and the insulating layer 18 including the pad 19 that electrically and physically bonds the light-emitting section 10 and the drive substrate 30 to each other, in this order.

It is to be noted that, although not illustrated, the electrode layer 12 is provided on the side of the surface 11S1 of the light-emitting element 11, and a voltage is applied to the second conductivity-type layer 113 via the electrode layer 12, as in the above-described first embodiment. It is not limited thereto, and a configuration may be adopted in which a voltage is applied from the side of the surface 11S2 of the light-emitting element 11 to the second conductivity-type layer 113.

The wavelength conversion section 20 is provided on the side of the light extraction surface S1 of the light-emitting section 10. The wavelength conversion section 20 includes the sapphire substrate 114 serving as a partition wall having, for example, the opening 114H for each of the light-emitting elements 11, and the wavelength conversion layer 23 formed in the opening 114H. The reflection film 24 is further provided between the sapphire substrate 114 and the wavelength conversion layer 23. The protective layer 25 is further provided on the side of the light outputting surface 22S1 of the wavelength conversion layer 23, and the wavelength selection layer 26 is further provided in the protective layer 25. The on-chip lens layer 27 is further provided on the protective layer 25.

The sapphire substrate 114 corresponds to a specific example of a “partition wall” of the present disclosure. When the light-emitting device 2 is applied to the image display apparatus 100, the sapphire substrate 114 suppresses an occurrence of color mixing due to light leakage between the sub-pixels (the red pixel Pr, the green pixel Pg, and the blue pixel Pb) of adjacent RGB. The sapphire substrate 114 has, for example, a honeycomb structure. Specifically, as illustrated in FIG. 10, the sapphire substrate 114 has, for example, the opening 114H having a substantially regular hexagonal shape for each of the plurality of light-emitting elements 11 disposed in an array. As illustrated in FIG. 10, an area of the opening 114H is smaller than an area of the surface 11S1 of each the plurality of light-emitting elements 11, and in a plan view, a portion of the sapphire substrate 114 overlaps with the surface 11S1 of each of the light-emitting elements 11 in a peripheral part of each of the light-emitting elements 11. In other words, the sapphire substrate 114 is in contact with the surface 11S1 of each of the light-emitting elements 11 in the peripheral part of each of the light-emitting elements 11. In other words, the peripheral part of each of the light-emitting elements 11 is covered with the sapphire substrate 114. A thickness of the sapphire substrate 114 is, for example, less than or equal to 1 μm, and is preferably, for example, about 500 nm.

Although FIG. 9 illustrates an example in which the opening 114H has a side surface that is provided upright in a substantially perpendicular direction with respect to the surface 11S1 of the light-emitting element 11, the present invention is not limited thereto. The opening 114H has, for example, an inclined surface of less than 90° with respect to the surface 20S2, of the wavelength conversion section 20, that is on an opposite side of the surface 20S1 in the cross-sectional view. That is, the sapphire substrate 114 may have a tapered shape between the adjacent color pixels Pr, Pg, and Pb in a cross-sectional view.

The wavelength conversion layer 23 corresponds to a specific example of a “wavelength conversion layer” of the present disclosure. The wavelength conversion layer 23 is for converting light outputted from the plurality of light-emitting elements 11 into a desired wavelength (for example, red (R)/green (G)/blue (B)) and outputting the converted light, and is formed in the opening 114H provided above the light-emitting elements 11. Specifically, the red pixel Pr is provided with a red wavelength conversion layer 23R that converts light outputted from the light-emitting element 11 into red band light (red light), the green pixel Pg is provided with a green wavelength conversion layer 23G that converts light outputted from the light-emitting element 11 into green band light (green light), and the blue pixel Pb is provided with a blue wavelength conversion layer 23B that converts light outputted from the light-emitting element 11 into blue band light (blue light).

It is possible to form each of the wavelength conversion layers 23R, 23G, and 23B using quantum dots corresponding to each color. In particular, in a case where the red light is to be obtained, it is possible to select the quantum dots from, for example, InP, GaInP, InAsP, CdSe, CdZnSe, CdTeSe, or CdTe. In a case where the green light is to be obtained, it is possible to select the quantum dots from, for example, InP, GaInP, ZnSeTe, ZnTe, CdSe, CdZnSe, CdS, or CdSeS. In a case where the blue light is to be obtained, it is possible to select the quantum dots from, for example, ZnSe, ZnTe, ZnSeTe, CdSe, CdZnSe, CdS, CdZnS, or CdSeS. It is to be noted that, in the case where the blue light is to be outputted from the light-emitting element 11 as described above, the blue wavelength conversion layer 23B may include a resin layer having a light-transmitting property.

The reflection film 24 is provided on a side surface of the opening 114H for efficiently extracting the respective pieces of color light outputted from the light-emitting elements 11 and converted in the respective wavelength conversion layers 23R, 23G, and 23B from a light extraction surface (a surface 22S1) of the wavelength conversion layer 23. The reflection film 24 is formed using a metal material having a light-reflecting property. Examples of the metal material that forms the reflection film 24 include a metal having a high reflectance in a visible light region. Specific examples of the material include silver (Ag), aluminum (Al), copper (Cu), gold (Au), platinum (Pt), rhodium (Rh), and an alloy thereof.

Note that the reflection film 24 does not necessarily have to be formed in a case where the sapphire substrate 114 is formed using the metal material having the light-reflecting property described above.

The drive substrate 30 is provided with a driving circuit or the like that controls driving of the plurality of light-emitting elements 11 arranged in the display section 100A. The drive substrate 30 includes: the support substrate 31; the interlayer insulating layer 32 that is provided on the support substrate 31 and includes the plurality of wiring layers (e.g., the wiring layers M1, M2, M3, M4, and M5); the insulating layer 33 forming the bonding surface with the light-emitting section 10; and the pad 34 embedded in the insulating layer 33.

### 2-2. Method of Manufacturing Light-Emitting Device

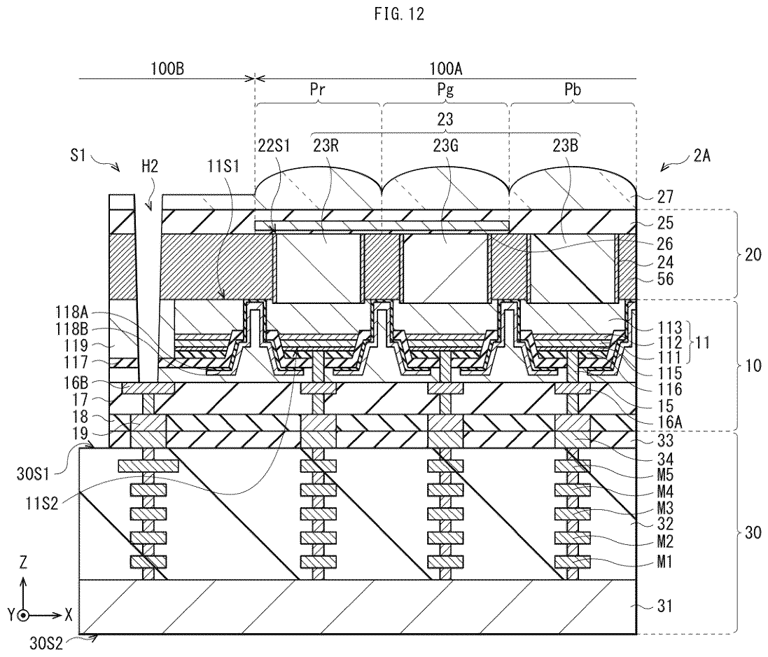

The light-emitting device 2 of the present embodiment is manufacturable, for example, as follows. FIGS. 11A to 11D illustrate exemplary manufacturing steps of the light-emitting device 2.

First, each of the singulated sapphire substrates 114 is so bonded that the insulating layer 116 faces the transfer substrate 52, following which the sapphire substrate 114 is thinned, for example, to have a thickness of 1 μm by, for example, grinding polishing, as in the above-described first embodiment. Thereafter, the plurality of pads 34 of the drive substrate 30 that has been separately formed and the plurality of pads 19 are bonded to each other by Cu-Cu bonding, following which the support substrate 55 is peeled off as illustrated in FIG. 11A, as in the above-described first embodiment.

Thereafter, as illustrated in FIG. 11B, the sapphire substrate 114 is patterned, and the opening 114H is formed above each of the light-emitting elements 11 using, for example, a photolithography technique. At this time, the compound semiconductor layer 110 is etched, and this causes a step to be formed on the surface 11S1 of each of the light-emitting elements 11. Note that, an etching selectivity ratio between the sapphire substrate 114 and the compound semiconductor layer 110 (for example, a Gan layer) is 5 or more and 10 or less, and thus, the compound semiconductor layer 110 is grinded about 100 nm with respect to over-etching of the sapphire substrate 114 of about 1 μm.

Thereafter, as illustrated in FIG. 11C, an Al film is formed on an upper surface of the sapphire substrate 114 and a side surface and a bottom surface of the opening 114H by, for example, a CVD method. Thereafter, the Al film formed on the upper surface of the sapphire substrate 114 and the bottom surface of the opening 114H is removed by etch-back to form the reflection film 24 on the side surface of the opening 114H.

Thereafter, as illustrated in FIG. 11D, the wavelength conversion layers 23 (23R, 23G, and 23B) of the respective colors are each formed in corresponding one of the openings 114H by a coating method such as an ink-jet method. Thereafter, the protective layer 25 containing the wavelength selection layer 26 is formed on the sapphire substrate 114 and the wavelength conversion layer 23, following which the on-chip lens layer 27 is bonded thereto, as in the first embodiment. Thus, the light-emitting device 2 illustrated in FIG. 9 is completed.

### 2-3. Workings and Effects

In the light-emitting device 2 of the present embodiment, the sapphire substrate 114, which is a growth substrate of the compound semiconductor layer 110 that configures the plurality of light-emitting elements 11 in the manufacturing process, is provided as a partition layer. The partition layer partitions the space on the side of the light extraction surface S1 of each of the plurality of light-emitting elements 11 disposed in an array. The space is partitioned for each of the light-emitting elements. The area of the opening 114H is smaller than the area of the surface 11S1 of each the plurality of light-emitting elements 11. The peripheral part of each of the light-emitting elements 11 is covered with the sapphire substrate 114. As a result, for example, the compound semiconductor layer 110 on the transfer substrate 52 or the support substrate 54 is reinforced, and peeling by the internal stress is suppressed.

Therefore, it is possible to improve a manufacturing yield of each of the light-emitting device 1 of the present embodiment and the image display apparatus 100 including the light-emitting device 1 of the present embodiment.

Further, in the present embodiment, the sapphire substrate 114, which is a growth substrate of the compound semiconductor layer 110 that configures the plurality of light-emitting elements 11 in the manufacturing process, is provided as a partition layer. The sapphire substrate 114 overlaps with, i.e., is in contact with, the surface 11S1 of each of the light-emitting elements 11 in the peripheral part of each of the light-emitting elements 11. Accordingly, as with the light-emitting device 1 of the above-described first embodiment, for example, adherence of the partition layer is improved as compared with a case where the partition layer includes a metal material or the like. This reduces a decrease in a manufacturing yield due to collapse or the like of the partition layer occurred during the manufacturing process. It is therefore possible to further improve the manufacturing yield of each of the light-emitting device 1 and the image display apparatus 100 including the light-emitting device 1. Furthermore, it is possible to form the partition layer having a large aspect ratio.

### 3. MODIFICATION EXAMPLES

### 3-1. Modification Example 1

FIG. 12 schematically illustrates an example of a cross-sectional configuration of a light-emitting device (a light-emitting device 2A) according to Modification example 2 of the present disclosure. The light-emitting device 2A is suitably applicable to a display section of an image display apparatus (the image display apparatus 100) which is what is called an LED display as in the above-described first and second embodiments.

In the second embodiment, the description has been given of the example in which the sapphire substrate 114 having a light-transmitting property is used as the growth substrate, and the sapphire substrate is used to form the partition layer; however, the present disclosure is not limited thereto. For example, a silicon (Si) substrate 56 having a light-shielding property or a silicon carbide (SiC) substrate may be used as the growth substrate to form the partition layer. In this case, the reflection film 24 may be omitted.

As described above, in the light-emitting device 2A of the present modification example, the partition layer is formed using, for example, the Si substrate 56 having a light-shielding property instead of the sapphire substrate 114 as the growth substrate. This makes it possible to achieve effects similar to those of the above-described embodiments, and to reduce manufacturing costs.

### 3-2. Modification Example 2

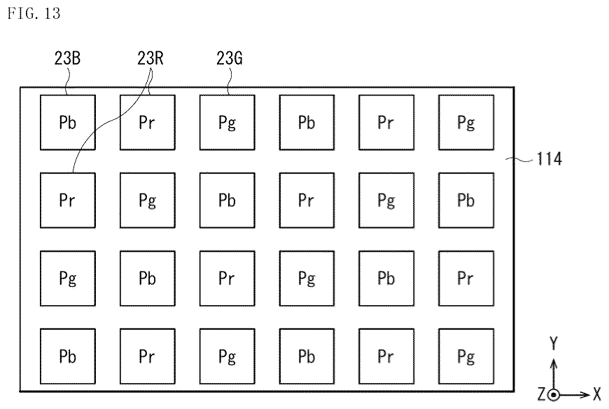

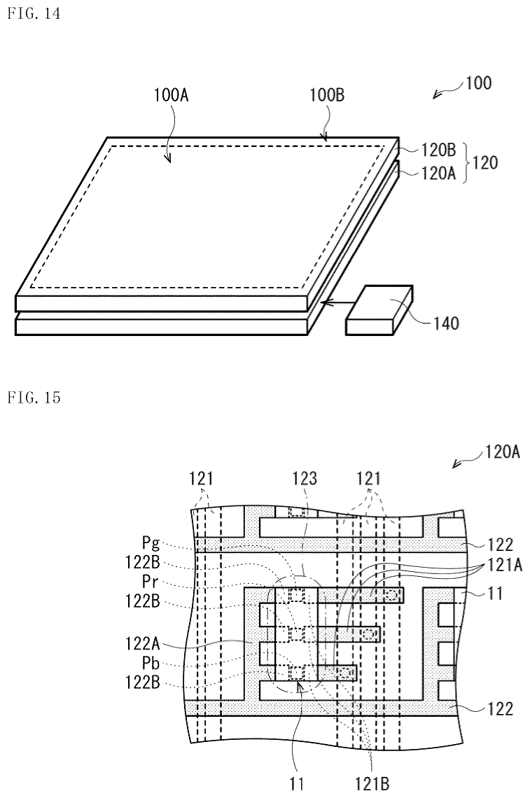

In the above-described first and second embodiments, the partition layer 22 has the opening 22H having a substantially regular hexagonal shape for each of the color pixels Pr, Pg, and Pb, but a planar shape of the opening 22H is not limited thereto. For example, as illustrated in FIG. 13, a rectangular opening 22H may be provided. In this case, the plurality of light-emitting elements 11 and the opening 22H may be two-dimensionally arranged in a matrix, for example. The wavelength conversion layers 23 (the red wavelength conversion layer 23A, the green wavelength conversion layer 23G, and the blue wavelength conversion layer 23B) provided in the respective openings 22H are arranged, for example, in a Bayer pattern.

### 4. APPLICATION EXAMPLES

### Application Example 1

FIG. 14 is a perspective diagram illustrating an example of a schematic configuration of an image display apparatus (the image display apparatus 100). The image display apparatus 100 is a so-called LED display, and a light-emitting device (for example, the light-emitting device 1) of the present disclosure is used as a display pixel. As illustrated in FIG. 14, for example, the image display apparatus 100 includes a display panel 120 and a control circuit 140 that drives the display panel 120.

The display panel 120 is a display panel in which a mounting substrate 120A and a counter substrate 120B are superimposed on each other. A surface of the counter substrate 120B serves as a picture display surface, and has a display region (a display section 100A) at a middle portion thereof, and a frame section 100B which is a non-display region is provided around the display region.

FIG. 15 is a diagram illustrating an exemplary wiring layout of a region corresponding to the display section 100A on the counter substrate 120B side of the mounting substrate 120A. As illustrated in FIG. 15, for example, a plurality of data wirings 121 is formed to extend in a predetermined direction and is arranged in parallel at a predetermined pitch in a region corresponding to the display section 100A of a surface of the mounting substrate 120A. In a region of the mounting substrate 120A corresponding to the display section 100A, for example, a plurality of scan wirings 122 is formed to extend in a direction intersecting (for example, orthogonal to) the data wirings 121, and is arranged in parallel at a predetermined pitch. The data wiring 121 and the scan wiring 122 include, for example, a conductive material such as Cu.

The scan wiring 122 is formed on, for example, an outermost layer, and is formed on, for example, an insulating layer (not illustrated) formed on a surface of a base material. The base material of the mounting substrate 120A is configured by, for example, a silicon substrate, a resin substrate, or the like, and the insulating layer on the base material includes, for example, SiN, SiO, aluminum oxide (AIO), or a resin material. On the other hand, the data wiring 121 is formed in a layer (for example, a layer lower than the outermost layer) different from the outermost layer that includes the scan wiring 122, and is formed in, for example, the insulating layer on the base material.

Near an intersection of the data wiring 121 and the scan wiring 122 is a display pixel 123, and a plurality of display pixels 123 is arranged in a matrix in the display section 100A. For example, each color pixel Pr, Pg, and Pb of the light-emitting device 1 is mounted on each of the display pixels 123.

In the light-emitting device 1, for example, a pair of terminal electrodes are provided for each color pixel Pr, Pg, and Pb, or a pair of terminal electrodes are provided in which one of the pair of terminal electrodes is commonly provided for each color pixel Pr, Pg, and Pb and the other of the pair of terminal electrodes is provided for each color pixel Pr, Pg, and Pb. One terminal electrode is electrically coupled to the data wiring 121, and the other terminal electrode is electrically coupled to the scan wiring 122. For example, one terminal electrode is electrically coupled to a pad electrode 121B at a distal end of a branch 121A provided at the data wiring 121. Further, for example, the other terminal electrode is electrically coupled to a pad electrode 122B at a distal end of a branch 122A provided at the scan wiring 122.

Each of the pad electrodes 121B and 122B is formed, for example, on the outermost layer, and is provided, for example, in a portion where each light-emitting device 1 is mounted, as illustrated in FIG. 15. Here, each of the pad electrodes 121B and 122B includes an electrically conductive material such as Au (gold).

The mounting substrate 120A is further provided with, for example, a plurality of support columns (not illustrated) that regulates a distance between the mounting substrate 120A and the counter substrate 120B. The support column may be provided in a region opposed to the display section 100A or may be provided in a region opposed to the frame section 100B.

The counter substrate 120B includes, for example, a glass substrate or a resin substrate. In the counter substrate 120B, a surface on the light-emitting device 1 side may be flat, but is preferably rough. The rough surface may be provided over the entire region opposed to the display section 100A, or may be provided only in a region opposed to the display pixel 123. The rough surface has fine irregularities in which the pieces of light emitted from the color pixels Pr, Pg, and Pb enter the rough surface. It is possible to fabricate the irregularities of the rough surface by, for example, sand blasting, dry etching, or the like.

The control circuit 140 drives each display pixel 123 (each light-emitting device 1) on the basis of on a picture signal. The control circuit 140 includes, for example, a data driver that drives the data wiring 121 coupled to the display pixel 123 and a scan driver that drives the scan wiring 122 coupled to the display pixel 123. For example, as illustrated in FIG. 14, the control circuit 140 may be provided separately from the display panel 120 and coupled to the mounting substrate 120A via a wiring, or may be mounted on the mounting substrate 120A.

### Application Example 2

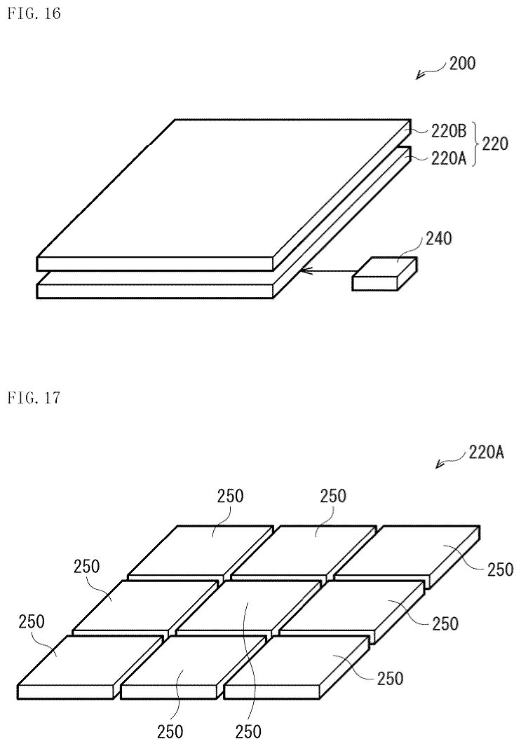

FIG. 16 is a perspective diagram illustrating another configuration example of the image display apparatus (an image display apparatus 200) using a light-emitting device (for example, the light-emitting device 1) of the present disclosure. The image display apparatus 200 is a so-called tiling display that uses a plurality of light-emitting devices in which LEDs are used as light sources. For example, as illustrated in FIG. 16, the image display apparatus 200 includes a display panel 220 and a control circuit 240 that drives the display panel 220.

The display panel 220 is a display panel in which a mounting substrate 220A and a counter substrate 220B are superimposed on each other. A surface of the counter substrate 220B serves as a picture display surface, and has a display section at a middle portion thereof, and a frame section which is a non-display region is provided around the display section (neither of which is illustrated). The counter substrate 220B is disposed, for example, at a position opposed to the mounting substrate 220A with a predetermined gap therebetween. The counter substrate 220B may be in contact with an upper surface of the mounting substrate 220A.

FIG. 17 schematically illustrates an example of a configuration of the mounting substrate 220A. For example, as illustrated in FIG. 17, the mounting substrate 220A includes a plurality of unit substrates 250 laid in a tile shape. Although FIG. 17 illustrates an example in which the mounting substrate 220A is configured by nine unit substrates 250, the number of unit substrates 250 may be 10 or more or 8 or less.

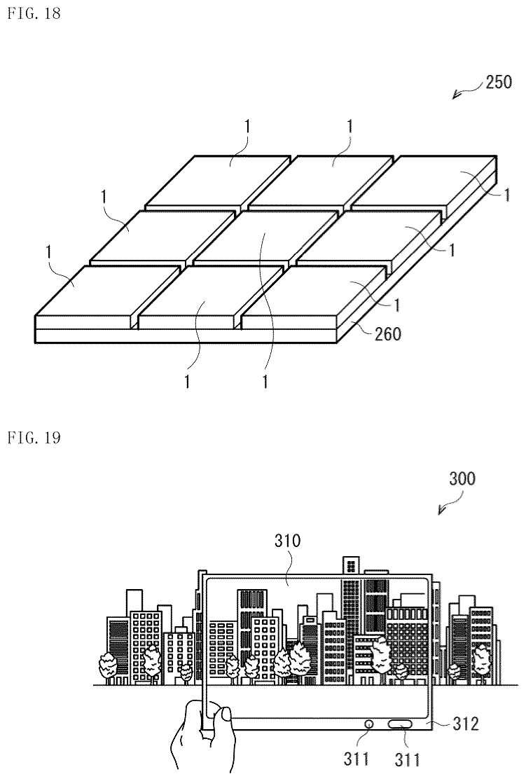

FIG. 18 illustrates an example of a configuration of the unit substrate 250. The unit substrate 250 includes, for example, a plurality of light-emitting devices 1 laid in tiles, and a support substrate 260 that supports the light-emitting devices 1. The unit substrate 250 further includes a control substrate (not illustrated). The support substrate 260 includes, for example, a metal frame (a metal plate), a wiring substrate, or the like. In a case where the support substrate 260 is configured by the wiring substrate, the support substrate 260 may also serve as a control substrate. At this time, at least one of the support substrate 260 or the control substrate is electrically coupled to each of the light-emitting devices 1.

### Application Example 3

FIG. 19 illustrates an appearance of a transparent display 300. The transparent display 300 includes, for example, a display unit 310, an operation unit 311, and a housing 312. A light-emitting device of the present disclosure (for example, the light-emitting device 1) is used for the display unit 310. The transparent display 300 is able to display an image and character information while allowing the background of the display unit 310 to transmit therethrough.

In the transparent display 300, a substrate having a light-transmitting property is used as a mounting substrate. Each electrode provided in the light-emitting device 1 is formed using an electrically conductive material having a light-transmitting property as in a case of the mounting substrate. Alternatively, each electrode has a structure that is difficult to be visually recognized by supplementing a wiring width or reducing a thickness of a wiring. Further, the transparent display 300 is able to perform black display by superimposing, for example, a liquid crystal layer including a driving circuit, and is able to perform switching between transmittance and black display by controlling a light distribution direction of liquid crystals.

Although the present technology has been described with reference to the first and second embodiments, Modification examples 1 and 2, and the application examples, the present technology is not limited to the above-described embodiment and the like, and various modification examples are possible. For example, in the above-described embodiments and the like, an example in which the light outputted from the light-emitting element 11 is blue light or ultraviolet light has been described, but it is not limited thereto. For example, in the light-emitting device 1, it is also possible to use a light-emitting element in which two or more kinds of light such as blue light and green light or ultraviolet light and green light are outputted.

Further, in the above-described embodiments and the like, the respective members configuring the light-emitting device 1, etc., have been specifically described, but it is not necessary to include all the members, and other members may be further provided.

It is to be noted that the effects described in the present specification are mere examples and description thereof is non-limiting.

The present technology may have the following configuration. According to the present technology having the following configuration, a growth substrate that forms an interface free of lattice mismatch is caused to remain on a portion of a light outputting surface of each of a plurality of light-emitting elements including a compound semiconductor. This makes it possible to prevent peeling of the light-emitting element and to improve a manufacturing yield.
(1)

A light-emitting device including:
a drive substrate;
a plurality of light-emitting elements each having a first surface and a second surface, the first surface being opposed to the drive substrate, the second surface being on an opposite side to the first surface and being a light outputting surface, the plurality of light-emitting elements being disposed in an array on a side of one surface of the drive substrate and each including a compound semiconductor; and
a growth substrate that is in contact with the second surface of each of the plurality of light-emitting elements, and forms an interface free of lattice mismatch with the compound semiconductor that configures each of the light-emitting elements.
(2)

The light-emitting device according to (1), in which the growth substrate is patterned to allow an aperture ratio of the second surface of each of the plurality of light-emitting elements to be greater than or equal to 50%.
(3)

The light-emitting device according to (1 ) or (2), in which the growth substrate is patterned in a stripe shape on the second surface of each of the plurality of light-emitting elements.
(4)

The light-emitting device according to (1) or (2), in which the growth substrate is patterned in a grid shape on the second surface of each of the plurality of light-emitting elements.
(5)

The light-emitting device according to any one of (1) to (4), in which the growth substrate is formed into a lens shape on the second surface of each of the plurality of light-emitting elements.
(6)

The light-emitting device according to (5), in which the growth substrate is formed into a concave lens shape in which a thickness of a middle part is smaller than a thickness of a peripheral part on the second surface of each of the plurality of light-emitting elements.
(7)

The light-emitting device according to any one of (2) to (6), in which an electrode layer having a light-transmitting property is formed on the second surface, of each of the plurality of light-emitting elements, that is exposed through an opening of the growth substrate.
(8)

The light-emitting device according to (7), in which the electrode layer serves as a common electrode for the plurality of light-emitting elements, and is formed continuously on the second surface of each of the plurality of light-emitting elements and on a side surface and an upper surface of the opening of the growth substrate.
(9)

The light-emitting device according to any one of (1) to (8), in which the growth substrate is provided between the plurality of light-emitting elements adjacent to each other, the growth substrate overlapping with the second surface in respective peripheral parts of the plurality of light-emitting elements.
(10)

The light-emitting device according to (9), in which the growth substrate configures a partition wall in a pixel array in which the plurality of light-emitting elements is disposed in an array, the partition wall partitioning a space above the second surface of each of the plurality of light-emitting elements, the space being partitioned for each of the light-emitting elements.
(11)

The light-emitting device according to (10), in which a wavelength conversion layer is further provided above the second surface of each of the plurality of light-emitting elements partitioned by the partition wall, the wavelength conversion layer converting a wavelength of light outputted from each of the plurality of light-emitting elements.
(12)

The light-emitting device according to (11), in which the light-emitting element includes a first light-emitting element, a second light-emitting element, and a third light-emitting element that output first light,
the wavelength conversion layer includes a first wavelength conversion layer disposed above the first light-emitting element, a second wavelength conversion layer disposed above the second light-emitting element, and a third wavelength conversion layer disposed above the third light-emitting element,
the first wavelength conversion layer converts the first light into red light, the second wavelength conversion layer converts the first light into green light, and the third wavelength conversion layer allows the first light to transmit therethrough or converts the first light into blue light.
(13)

The light-emitting device according to any one of (1) to (12), in which the growth substrate includes a sapphire substrate.
(14)

The light-emitting device according to any one of (1) to (13), in which the light-emitting element includes a light-emitting diode having a light emission wavelength in a blue band or an ultraviolet region.
(15)

A method of manufacturing a light-emitting device, the method including:
epitaxially growing a compound semiconductor layer including an active layer on a growth substrate;
singulating the compound semiconductor layer, together with the growth substrate, into a plurality of pieces;
bonding the compound semiconductor layer having been singulated to a first support substrate with the growth substrate being opposed to the first support substrate;
forming a plurality of light-emitting elements by separating the compound semiconductor layer; and
causing a portion of the growth substrate to remain on a light outputting surface of each of the plurality of light-emitting elements by bonding the plurality of light-emitting elements to a second support substrate together with the growth substrate and thereafter grinding the growth substrate.
(16)

An image display apparatus, including
a light-emitting device,
the light-emitting device including
a drive substrate,
a plurality of light-emitting elements each having a first surface and a second surface, the first surface being opposed to the drive substrate, the second surface being on an opposite side to the first surface and being a light outputting surface, the plurality of light-emitting elements being disposed in an array on a side of one surface of the drive substrate and each including a compound semiconductor, and
a growth substrate that is in contact with the second surface of each of the plurality of light-emitting elements, and forms an interface free of lattice mismatch with the compound semiconductor that configures each of the light-emitting elements.
(17)

A light-emitting device including:
a drive substrate,
a plurality of light-emitting elements each having a first surface and a second surface, the first surface being opposed to the drive substrate, the second surface being on an opposite side to the first surface and being a light outputting surface, the plurality of light-emitting elements being disposed in an array on a side of one surface of the drive substrate and each including a compound semiconductor; and
a growth substrate that is in contact with the second surface of each of the plurality of light-emitting elements, and configures a partition wall partitioning a space above the second surface of each of the plurality of light-emitting elements, the space being partitioned for each of the light-emitting elements.
(18)

The light-emitting device according to (17), in which the growth substrate is provided between the plurality of light-emitting elements adjacent to each other, the growth substrate overlapping with the second surface in respective peripheral parts of the plurality of light-emitting elements.

The present application claims the benefit of Japanese Priority Patent Application JP 2022-175801 filed with the Japan Patent Office on Nov. 1, 2022, the entire contents of which are incorporated herein by reference.

It should be understood by those skilled in the art that various modifications, combinations, sub-combinations, and alterations may occur depending on design requirements and other factors insofar as they are within the scope of the appended claims or the equivalents thereof.

What is claimed is:

1. A light-emitting device, comprising:
a drive substrate;
a plurality of light-emitting elements each having a first surface and a second surface, the first surface being opposed to the drive substrate, the second surface being on an opposite side to the first surface and being a light outputting surface, the plurality of light-emitting elements being disposed in an array on a side of one surface of the drive substrate and each including a compound semiconductor; and
a growth substrate that is in contact with the second surface of each of the plurality of light-emitting elements, and forms an interface free of lattice mismatch with the compound semiconductor that configures each of the light-emitting elements.

2. The light-emitting device according to claim 1, wherein the growth substrate is patterned to allow an aperture ratio of the second surface of each of the plurality of light-emitting elements to be greater than or equal to 50%.

3. The light-emitting device according to claim 1, wherein the growth substrate is patterned in a stripe shape on the second surface of each of the plurality of light-emitting elements.

4. The light-emitting device according to claim 1, wherein the growth substrate is patterned in a grid shape on the second surface of each of the plurality of light-emitting elements.

5. The light-emitting device according to claim 1, wherein the growth substrate is formed into a lens shape on the second surface of each of the plurality of light-emitting elements.

6. The light-emitting device according to claim 5, wherein the growth substrate is formed into a concave lens shape in which a thickness of a middle part is smaller than a thickness of a peripheral part on the second surface of each of the plurality of light-emitting elements.

7. The light-emitting device according to claim 2, wherein an electrode layer having a light-transmitting property is formed on the second surface, of each of the plurality of light-emitting elements, that is exposed through an opening of the growth substrate.

8. The light-emitting device according to claim 7, wherein the electrode layer serves as a common electrode for the plurality of light-emitting elements, and is formed continuously on the second surface of each of the plurality of light-emitting elements and on a side surface and an upper surface of the opening of the growth substrate.

9. The light-emitting device according to claim 1, wherein the growth substrate is provided between the plurality of light-emitting elements adjacent to each other, the growth substrate overlapping with the second surface in respective peripheral parts of the plurality of light-emitting elements.

10. The light-emitting device according to claim 9, wherein the growth substrate configures a partition wall in a pixel array in which the plurality of light-emitting elements is disposed in an array, the partition wall partitioning a space above the second surface of each of the plurality of light-emitting elements, the space being partitioned for each of the light-emitting elements.

11. The light-emitting device according to claim 10, wherein a wavelength conversion layer is further provided above the second surface of each of the plurality of light-emitting elements partitioned by the partition wall, the wavelength conversion layer converting a wavelength of light outputted from each of the plurality of light-emitting elements.

12. The light-emitting device according to claim 11, wherein
the light-emitting element comprises a first light-emitting element, a second light-emitting element, and a third light-emitting element that output first light,
the wavelength conversion layer comprises a first wavelength conversion layer disposed above the first light-emitting element, a second wavelength conversion layer disposed above the second light-emitting element, and a third wavelength conversion layer disposed above the third light-emitting element,
the first wavelength conversion layer converts the first light into red light,
the second wavelength conversion layer converts the first light into green light, and
the third wavelength conversion layer allows the first light to transmit therethrough or converts the first light into blue light.

13. The light-emitting device according to claim 1,
wherein the growth substrate comprises a sapphire substrate.

14. The light-emitting device according to claim 1, wherein the light-emitting element comprises a light-emitting diode having a light emission wavelength in a blue band or an ultraviolet region.

15. A method of manufacturing a light-emitting device, the method comprising:
epitaxially growing a compound semiconductor layer including an active layer on a growth substrate;
singulating the compound semiconductor layer, together with the growth substrate, into a plurality of pieces;
bonding the compound semiconductor layer having been singulated to a first support substrate with the growth substrate being opposed to the first support substrate;
forming a plurality of light-emitting elements by separating the compound semiconductor layer; and
causing a portion of the growth substrate to remain on a light outputting surface of each of the plurality of light-emitting elements by bonding the plurality of light-emitting elements to a second support substrate together with the growth substrate and thereafter grinding the growth substrate.

16. An image display apparatus, comprising
a light-emitting device,
the light-emitting device including
a drive substrate,
a plurality of light-emitting elements each having a first surface and a second surface, the first surface being opposed to the drive substrate, the second surface being on an opposite side to the first surface and being a light outputting surface, the plurality of light-emitting elements being disposed in an array on a side of one surface of the drive substrate and each including a compound semiconductor, and
a growth substrate that is in contact with the second surface of each of the plurality of light-emitting elements, and forms an interface free of lattice mismatch with the compound semiconductor that configures each of the light-emitting elements.
